(19) United States
(12) Patent Application Publication
(10) Pub. No.: US 2026/0344039 A1
(43) Pub. Date: Oct. 29, 2026

(54) Semiconductor Device

(71) Applicant: Samsung Electronics Co., Ltd., Suwon-si (KR)

(72) Inventors: Jinchan Yun, Suwon-si (KR); Sungil Park, Suwon-si (KR); Jae Hyun Park, Suwon-si (KR)

(21) Appl. No.: 19/391,420

(22) Filed: Nov. 17, 2025

(30) Foreign Application Priority Data
Apr. 25, 2025 (KR) 10-2025-0054590

(51) Int. Cl. H10D 84/85; H10D 84/01

(52) U.S. Cl. CPC H10D 84/856; H10D 84/0186; H10D 84/851

(57) ABSTRACT

A semiconductor device includes a plurality of lower sheet patterns spaced apart from one another in a first direction and a plurality of upper sheet patterns spaced apart from one another in the first direction on the plurality of lower sheet patterns. The device has a gate electrode structure surrounding each of the plurality of lower sheet patterns and each of the plurality of upper sheet patterns, and the gate electrode structure extends in a second direction intersecting the first direction. A lower gate contact is disposed under the gate electrode structure and overlaps the plurality of lower sheet patterns in the first direction. A first liner film is disposed on a side surface of the lower gate contact, wherein a width of the gate electrode structure in the second direction may decrease downward along the first direction.

### CROSS-REFERENCE TO RELATED APPLICATION(S)

This application claims priority to Korean Patent Application No. 10-2025-0054590, filed in the Korean Intellectual Property Office on Apr. 25, 2025, the entire contents of which are hereby incorporated by reference.

### BACKGROUND

The present disclosure relates to a semiconductor device.

A semiconductor device is a core component that controls or amplifies electrical signals in an electronic apparatus, and various kinds of semiconductor devices may be manufactured. For example, a memory device may mainly be used to store and retrieve data, and a non-memory device may be used to control or amplify electrical signals. A semiconductor device is a core element of an electronic apparatus and plays an important role in diverse fields, including computers, communication equipment, and consumer electronics.

As industry develops, the performance and functional requirements of electronic apparatuses are continuously increasing. Accordingly, high-performance characteristics of semiconductor devices are indispensably required, and to satisfy such requirements, the integration density of semiconductor devices is increasing. Various methods for forming semiconductor devices having excellent performance and improved integration density are being studied.

### SUMMARY

An object to be solved by the present disclosure is to provide a semiconductor device having improved electrical characteristics and integration density.

Another object to be solved by the present disclosure is to provide a method of manufacturing a semiconductor device having improved electrical characteristics and integration density.

According to some implementations of the present disclosure, a semiconductor device may include a plurality of lower sheet patterns spaced apart from one another in a first direction, a plurality of upper sheet patterns spaced apart from one another in the first direction on the plurality of lower sheet patterns, a gate electrode structure surrounding each of the plurality of lower sheet patterns and each of the plurality of upper sheet patterns, and the gate electrode structure extending in a second direction intersecting the first direction, a lower gate contact disposed under the gate electrode structure and overlapping the plurality of lower sheet patterns in the first direction and a first liner film disposed on a side surface of the lower gate contact, wherein a width of the gate electrode structure in the second direction may decrease downward along the first direction.

According to some implementations of the present disclosure, a semiconductor device may include a plurality of lower sheet patterns spaced apart from one another in a first direction, a plurality of upper sheet patterns spaced apart from one another in the first direction on the plurality of lower sheet patterns, a gate electrode structure surrounding each of the plurality of lower sheet patterns and each of the plurality of upper sheet patterns, and the gate electrode structure extending in a second direction intersecting the first direction, a gate insulating film disposed between the plurality of upper sheet patterns and the gate electrode structure and between the plurality of lower sheet patterns and the gate electrode structure, a lower gate contact disposed under the gate electrode structure, a lower source/drain pattern disposed on one side of the plurality of lower sheet patterns, a lower source/drain contact connected to the lower source/drain pattern and extending into a lower surface of the lower source/drain pattern; and a first liner film and a second liner film disposed between the lower gate contact and the lower source/drain contact, wherein the lower gate contact and the lower source/drain contact may overlap each other in a third direction intersecting each of the first direction and the second direction.

According to some implementations of the present disclosure, a semiconductor device may include a plurality of lower sheet patterns spaced apart from one another in a first direction, a plurality of upper sheet patterns spaced apart from one another in the first direction above the plurality of lower sheet patterns, a gate electrode structure surrounding each of the plurality of lower sheet patterns and each of the plurality of upper sheet patterns, and the gate electrode structure extending in a second direction intersecting the first direction, a lower gate contact disposed under the gate electrode structure and overlapping the plurality of lower sheet patterns in the first direction, a first liner film disposed on a side surface of the lower gate contact, a lower source/drain pattern disposed on one side of the plurality of lower sheet patterns, an upper source/drain pattern disposed on one side of the plurality of upper sheet patterns, a lower source/drain contact connected to the lower source/drain pattern, a second liner film disposed between the lower source/drain contact and the first liner film, a gate separation structure extending in a third direction intersecting each of the first direction and the second direction and disposed on a side surface of the gate electrode structure, and a gate insulating film may be disposed between the plurality of lower sheet patterns and the gate electrode structure, between the plurality of upper sheet patterns and the gate electrode structure, and between the first liner film and the gate electrode structure, wherein the lower source/drain contact may overlap the lower gate contact in the third direction.

According to some implementations of the present disclosure, a method of manufacturing a semiconductor device includes forming a plurality of lower sheet patterns spaced apart from one another in a first direction on a lower pattern of a substrate and a plurality of upper sheet patterns spaced apart from the plurality of lower sheet patterns in the first direction, forming a pre-semiconductor pattern disposed on the substrate and a lower source/drain pattern disposed on the pre-semiconductor pattern, forming a gate insulating film on the plurality of lower sheet patterns and the plurality of upper sheet patterns, forming a gate electrode structure surrounding each of the plurality of lower sheet patterns and the plurality of upper sheet patterns and extending in a second direction intersecting the first direction, forming a first liner film on the gate insulating film, forming a lower source/drain contact connected to the lower source/drain pattern, and forming a lower gate contact disposed on the first liner film, overlapping the plurality of lower sheet patterns in the first direction, and connected to the gate electrode structure.

According to some implementations, forming the first liner film may include removing the lower pattern so as to expose the gate insulating film, and forming the first liner film on the exposed gate insulating film.

According to some implementations, the method of manufacturing the semiconductor device may further include, after forming the first liner film on the gate insulating film, forming a sacrificial insulating pattern on the first liner film, forming a first trench by removing a portion of the gate electrode structure by using the sacrificial insulating pattern as an etching mask, and forming a gate separation structure on the first trench.

According to some implementations, forming the lower gate contact may include forming a second trench by removing a portion of the first liner film, a portion of the gate insulating film, and a portion of the gate electrode structure, and forming the lower gate contact on the second trench.

According to some implementations, a side surface of the second trench may include a first portion and a second portion having different slopes.

According to some implementations, forming the lower source/drain contact may include removing the pre-semiconductor pattern so as to expose the lower source/drain pattern, forming a second liner film on a lower surface of the lower source/drain pattern and on the first liner film, removing a portion of the second liner film, and forming the lower source/drain contact on the second liner film and the lower source/drain pattern.

According to some implementations, the first liner film and the second liner film may be disposed between the lower source/drain contact and the lower gate contact.

According to some implementations, the lower gate contact and the lower source/drain contact may overlap each other in a third direction intersecting each of the first direction and the second direction.

According to some implementations, the first liner film may include a material different from the plurality of lower sheet patterns.

According to some implementations, the first liner film may surround a side surface of the lower gate contact.

According to some implementations of the present disclosure, by disposing the lower gate contact so as to overlap the plurality of sheet patterns, the area of the gate electrode structure may be reduced. Accordingly, electrical characteristics and integration density of the semiconductor device may be improved.

### BRIEF DESCRIPTION OF THE DRAWINGS

The above and other implementations and features of the present disclosure will become more apparent by describing example implementations in detail with reference to the attached drawings, in which:

FIG. 1 is an exemplary plan view illustrating a semiconductor device according to some implementations of the present disclosure.

FIG. 2 is a cross-sectional view illustrating a cut taken along line A-A′ of FIG. 1.

FIG. 3 is a cross-sectional view illustrating a cut taken along line B-B′ of FIG. 1.

FIG. 4 is an enlarged view illustrating region Q1 of FIG. 3.

FIG. 5 is an enlarged view illustrating region Q1 of FIG. 3.

FIG. 6 is a view illustrating a semiconductor device according to some implementations of the present disclosure.

FIG. 7 is a view illustrating a semiconductor device according to some implementations of the present disclosure.

FIG. 8 is a view illustrating a semiconductor device according to some implementations of the present disclosure.

FIG. 9 is a view illustrating a semiconductor device according to some implementations of the present disclosure.

FIG. 10 is a view illustrating a semiconductor device according to some implementations of the present disclosure.

FIGS. 11 and 12 are views illustrating a semiconductor device according to some implementations of the present disclosure.

FIGS. 13-32 are views illustrating a method of manufacturing a semiconductor device according to some implementations of the present disclosure.

FIGS. 33-42 are views illustrating a method of manufacturing a semiconductor device according to some implementations of the present disclosure.

### DETAILED DESCRIPTION

In the present disclosure, the terms “upper,” “lower,” “upper surface,” and “lower surface” are provided for convenience of explanation and are not intended to limit the disclosure. The terms “upper,” “lower,” “upper surface,” and “lower surface” are described based on the drawings, and when the drawings are rotated upside down, terms designating the vertical relationship may be changed.

As used herein, the term “at least one of” can refer to and encompass any and all possible combinations of one or more of the associated listed terms. For example, the term “at least one of A, B, or C” means that (i) at least one of A, (ii) at least one of B, (iii) at least one of C, (iv) at least one of A and at least one of B, (v) at least one of B and at least one of C, (vi) at least one of A and at least one of C, or (vi) at least one of A, at least one of B and at least one of C are possible, where A, B and C may be singular or plural.

Hereinafter, with reference to the drawings, semiconductor devices and methods of manufacturing the same according to some implementations of the present disclosure will be described in detail.

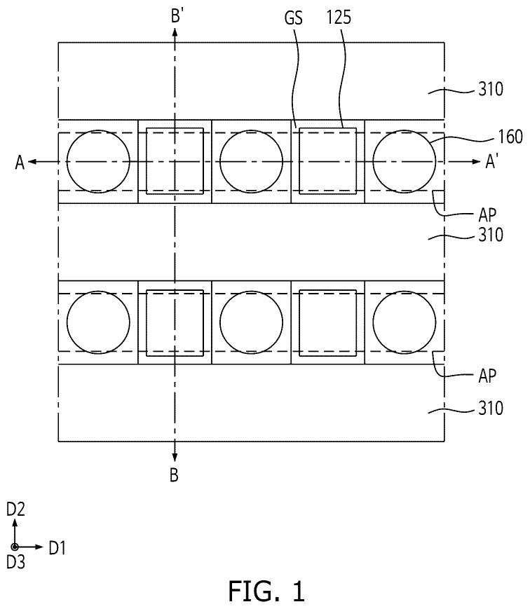

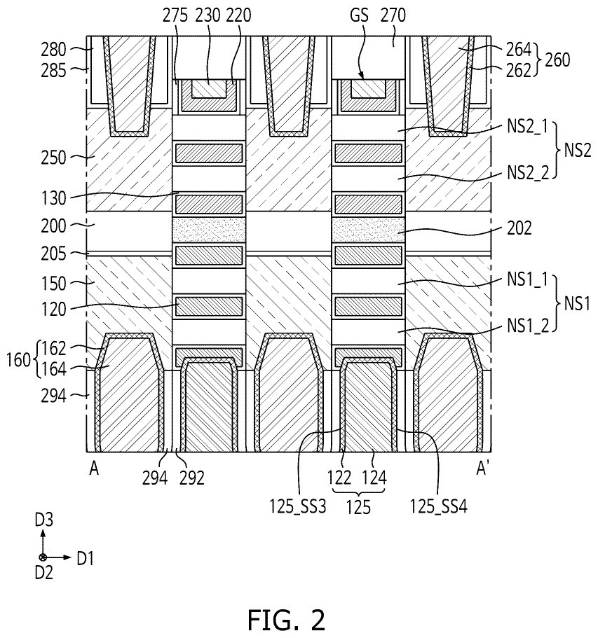

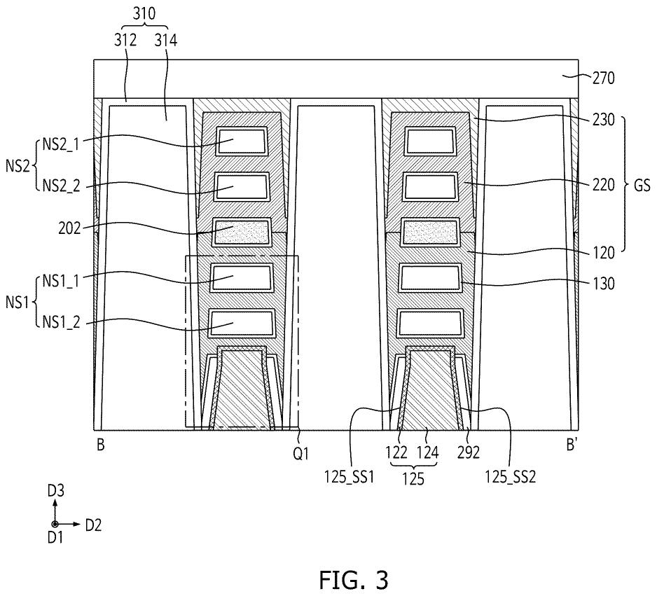

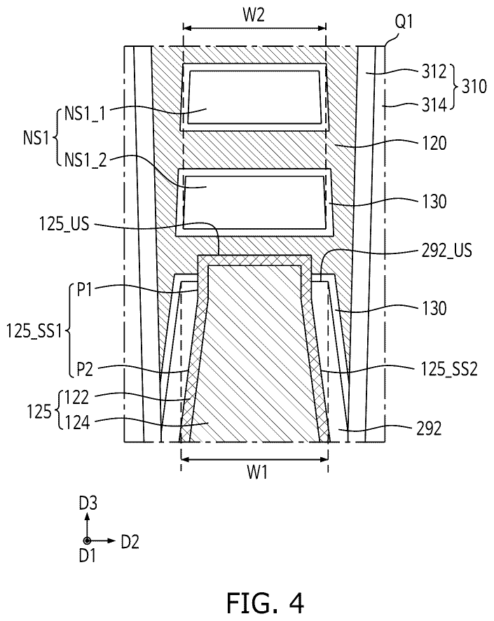

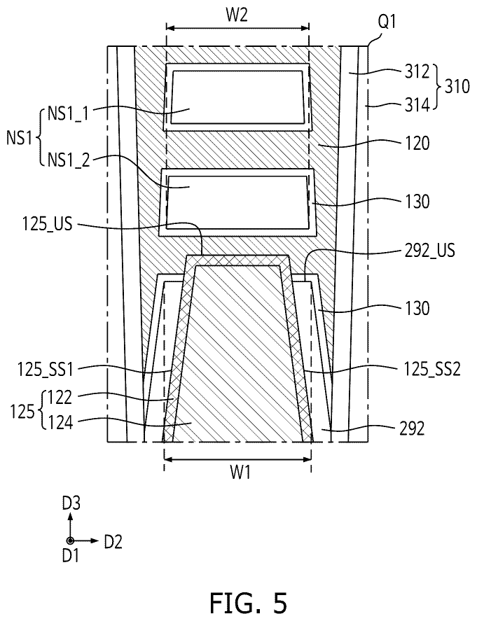

FIG. 1 is an exemplary plan view illustrating a semiconductor device according to some implementations of the present disclosure. FIG. 2 is a cross-sectional view illustrating a cut taken along line A-A′ of FIG. 1. FIG. 3 is a cross-sectional view illustrating a cut taken along line B-B′ of FIG. 1. FIG. 4 is an enlarged view illustrating region Q1 of FIG. 3. FIG. 5 is an enlarged view illustrating region Q1 of FIG. 3. For reference, FIG. 1 focuses on a gate electrode structure GS, a lower gate contact 125, and a lower source/drain contact 160.

Referring to FIGS. 1-5, a semiconductor device according to some implementations may include a plurality of lower sheet patterns NS1, a plurality of upper sheet patterns NS2, a gate electrode structure GS, a lower gate contact 125, a first liner film 292, a lower source/drain pattern 150, a lower source/drain contact 160, a second liner film 294, a middle interlayer insulating film 200, a middle insulating pattern 202, an upper source/drain pattern 250, an upper source/drain contact 260, a gate capping pattern 270, a gate spacer 275, and a gate separation structure 310.

The semiconductor device according to some implementations may include a metal-oxide-semiconductor field-effect transistor (MOSFET) and, more specifically, a three-dimensional multi-stack semiconductor device referred to as a gate-all-around (GAA) transistor or a multi-bridge-channel field-effect transistor (MBCFET).

An active region AP may be a region in which the plurality of lower sheet patterns NS1, the lower source/drain pattern 150, the plurality of upper sheet patterns NS2, and the upper source/drain pattern 250, which will be described below, are disposed. The active region AP may extend in a first direction D1. The first direction D1 may intersect a second direction D2. For example, the first direction D1 may be perpendicular to the second direction D2. A third direction D3 may intersect each of the first direction D1 and the second direction D2. For example, the third direction D3 may be perpendicular to each of the first direction D1 and the second direction D2.

The plurality of lower sheet patterns NS1 may be disposed on the active region AP. Each of the plurality of lower sheet patterns NS1 may be spaced apart from one another in the third direction D3. Each of the plurality of lower sheet patterns NS1 may have the shape of a nanosheet. Although two lower sheet patterns NS1 are illustrated, the present disclosure is not limited thereto.

Each lower sheet pattern NS1 may include one of elemental semiconductor silicon (Si), silicon germanium (SiGe), a IV-IV compound semiconductor, or a III-V compound semiconductor. The IV-IV compound semiconductor may be, for example, a binary or ternary compound including at least two of carbon (C), silicon (Si), germanium (Ge), and tin (Sn). The III-V compound semiconductor may be, for example, one of a binary, ternary, or quaternary compound formed by combining at least one Group III element—aluminum (Al), gallium (Ga), or indium (In)—and one Group V element—phosphorus (P), arsenic (As), or antimony (Sb).

The plurality of lower sheet patterns NS1 may include a first lower sheet pattern NS1_1 and a second lower sheet pattern NS1_2. The first lower sheet pattern NS1_1 may be disposed on the second lower sheet pattern NS1_2. The second lower sheet pattern NS1_2 may be disposed on the lower gate contact 125, which will be described below.

The widths of the first lower sheet pattern NS1_1 and the second lower sheet pattern NS1_2 in the second direction D2 may not be constant. For example, the widths of the first lower sheet pattern NS1_1 and the second lower sheet pattern NS1_2 in the second direction D2 may increase as they become further away from the gate capping pattern 270. In a cross-sectional view, each of the first lower sheet pattern NS1_1 and the second lower sheet pattern NS1_2 may have a tapered side surface.

The plurality of upper sheet patterns NS2 may be disposed on the active region AP. The plurality of upper sheet patterns NS2 may be spaced apart from the plurality of lower sheet patterns NS1 in the third direction D3. The plurality of upper sheet patterns NS2 may overlap the plurality of lower sheet patterns NS1 in the third direction D3.

Each of the plurality of upper sheet patterns NS2 may have the shape of a nanosheet. Each of the plurality of upper sheet patterns NS2 may be spaced apart from one another in the third direction D3. Although two upper sheet patterns NS2 are illustrated, the present disclosure is not limited thereto.

The description of the material of the upper sheet pattern NS2 may be identical to the description of the material of the lower sheet pattern NS1. In some implementations, the material of the upper sheet pattern NS2 may be identical to the material of the lower sheet pattern NS1. However, the present disclosure is not limited thereto. For example, the material of the upper sheet pattern NS2 may differ from the material of the lower sheet pattern NS1.

The plurality of upper sheet patterns NS2 may include a first upper sheet pattern NS2_1 and a second upper sheet pattern NS2_2. The first upper sheet pattern NS2_1 may be disposed on the second upper sheet pattern NS2_2. The second upper sheet pattern NS2_2 may be disposed on the middle insulating pattern 202.

The widths of the first upper sheet pattern NS2_1 and the second upper sheet pattern NS2_2 in the second direction D2 may not be constant. For example, the widths of the first upper sheet pattern NS2_1 and the second upper sheet pattern NS2_2 in the second direction D2 may increase as they become further away from the gate capping pattern 270. In terms of cross-section, each of the first upper sheet pattern NS2_1 and the second upper sheet pattern NS2_2 may have a tapered shape. The width of the plurality of upper sheet patterns NS2 in the second direction D2 may be smaller than the width of the plurality of lower sheet patterns NS1 in the second direction D2, although the present disclosure is not limited thereto.

The middle insulating pattern 202 may be disposed between the plurality of upper sheet patterns NS2 and the plurality of lower sheet patterns NS1. The middle insulating pattern 202 may overlap the plurality of upper sheet patterns NS2 and the plurality of lower sheet patterns NS1 in the third direction D3. The middle insulating pattern 202 may include an insulating material. For example, the middle insulating pattern 202 may include silicon nitride. However, the present disclosure is not limited thereto.

In some implementations, the middle insulating pattern 202 may be omitted. In the position where the middle insulating pattern 202 is omitted, the upper sheet pattern NS2 or the lower sheet pattern NS1 may be disposed.

The gate electrode structure GS may be disposed on the middle insulating pattern 202, the plurality of lower sheet patterns NS1, and the plurality of upper sheet patterns NS2. The gate electrode structure GS may surround the middle insulating pattern 202, the plurality of lower sheet patterns NS1, and the plurality of upper sheet patterns NS2. The gate electrode structure GS may extend in the second direction D2. The gate electrode structure GS may intersect the active region AP.

The width of the gate electrode structure GS in the second direction D2 may not be constant. For example, the width of the gate electrode structure GS in the second direction D2 may decrease downward along the third direction D3. Stated differently, the width of the gate electrode structure GS in the second direction D2 may decrease as it becomes further away from the gate capping pattern 270, which will be described below. In terms of cross-section, the gate electrode structure GS may have a tapered shape.

The gate electrode structure GS may include a first metal pattern 120, a second metal pattern 220, and a third metal pattern 230.

The first metal pattern 120 may be disposed on the plurality of lower sheet patterns NS1. The first metal pattern 120 may surround the plurality of lower sheet patterns NS1. The first metal pattern 120 may surround four surfaces of each lower sheet pattern NS1. For example, the first metal pattern 120 may surround the upper surface, lower surface, and both side surfaces of each lower sheet pattern NS1. Here, the upper and lower surfaces of each lower sheet pattern NS1 refer to surfaces facing each other in the third direction D3, and both side surfaces of each lower sheet pattern NS1 refer to surfaces facing each other in the second direction D2.

The first metal pattern 120 may be disposed between the second lower sheet pattern NS1_2 and the lower gate contact 125. The first metal pattern 120 may be disposed between the second lower sheet pattern NS1_2 and the first lower sheet pattern NS1_1. The first metal pattern 120 may be disposed between the first lower sheet pattern NS1_1 and the middle insulating pattern 202. The first metal pattern 120 may be disposed on an upper surface and a side surface of the lower gate contact 125. For example, the first metal pattern 120 may be disposed between a side surface of the lower gate contact 125 and the gate separation structure 310.

The second metal pattern 220 may be disposed on the first metal pattern 120. In some implementations, the second metal pattern 220 may contact the first metal pattern 120. For example, a lower surface of the second metal pattern 220 may contact an upper surface of the first metal pattern 120. However, the present disclosure is not limited thereto. For example, the second metal pattern 220 may be spaced apart from the first metal pattern 120 in the third direction D3, and an insulating layer may be disposed between the second metal pattern 220 and the first metal pattern 120. In some implementations, the middle insulating pattern 202 may be disposed between the first metal pattern 120 and the second metal pattern 220. The first metal pattern 120 and the second metal pattern 220 may surround the middle insulating pattern 202.

The second metal pattern 220 may surround the plurality of upper sheet patterns NS2. The second metal pattern 220 may surround four surfaces of each upper sheet pattern NS2. For example, the second metal pattern 220 may surround the upper surface, lower surface, and both side surfaces of each upper sheet pattern NS2. Here, the upper and lower surfaces of each upper sheet pattern NS2 refer to surfaces facing each other in the third direction D3, and both side surfaces of each upper sheet pattern NS2 refer to surfaces facing each other in the second direction D2.

The second metal pattern 220 may be disposed between the second upper sheet pattern NS2_2 and the middle insulating pattern 202. The second metal pattern 220 may be disposed between the second upper sheet pattern NS2_2 and the first upper sheet pattern NS2_1.

In some implementations, each of the first metal pattern 120 and the second metal pattern 220 may be a work-function adjustment film for adjusting a threshold voltage of a transistor that uses the gate electrode structure GS as a gate electrode. The first metal pattern 120 may be a conductive work-function adjustment film different from the second metal pattern 220. For example, the first metal pattern 120 may be a p-type work-function adjustment film and the second metal pattern 220 may be an n-type work-function adjustment film. In another example, the first metal pattern 120 may be an n-type work-function adjustment film and the second metal pattern 220 may be a p-type work-function adjustment film.

The first metal pattern 120 may include at least one of Mo, Pd, Ru, Pt, TiN, WN, TaN, Ir, TaC, RuN, or MoN. The second metal pattern 220 may include at least one of TiAIC, TiAIN, TiAIC-N, TiAl, TaAIC, TaAIN, TaAIC-N, or TaAl, although the present disclosure is not limited thereto.

The third metal pattern 230 may be disposed on the second metal pattern 220. Although the third metal pattern 230 is illustrated as not contacting the first metal pattern 120, the present disclosure is not limited thereto. For example, the third metal pattern 230 may be disposed on a side surface of the first metal pattern 120.

The third metal pattern 230 may include at least one of a metal, a metal alloy, a conductive metal nitride, a metal silicide, a doped semiconductor material, a conductive metal oxide, or a conductive metal oxynitride. For example, the third metal pattern 230 may include at least one of titanium nitride (TiN), tantalum carbide (TaC), tantalum nitride (TaN), titanium silicon nitride (TiSiN), tantalum silicon nitride (TaSiN), tantalum titanium nitride (TaTiN), titanium aluminum nitride (TiAIN), tantalum aluminum nitride (TaAIN), tungsten nitride (WN), ruthenium (Ru), titanium aluminum (TiAl), titanium aluminum carbonitride (TiAIC-N), titanium aluminum carbide (TiAIC), titanium carbide (TIC), tantalum carbonitride (TaCN), tungsten (W), aluminum (Al), copper (Cu), cobalt (Co), titanium (Ti), tantalum (Ta), nickel (Ni), platinum (Pt), nickel-platinum (Ni—Pt), niobium (Nb), niobium nitride (NbN), niobium carbide (NbC), molybdenum (Mo), molybdenum nitride (MoN), molybdenum carbide (MoC), tungsten carbide (WC), rhodium (Rh), palladium (Pd), iridium (Ir), osmium (Os), silver (Ag), gold (Au), zinc (Zn), vanadium (V), or a combination thereof, but the present disclosure is not limited thereto. The conductive metal oxide and the conductive metal oxynitride may include oxidized forms of the above materials, but the present disclosure is not limited thereto.

A gate insulating film 130 may be disposed between the gate electrode structure GS and the plurality of lower sheet patterns NS1, between the gate electrode structure GS and the plurality of upper sheet patterns NS2, and between the gate electrode structure GS and the middle insulating pattern 202. For example, the gate insulating film 130 may be disposed between the first metal pattern 120 and the plurality of lower sheet patterns NS1. The gate insulating film 130 may be disposed between the second metal pattern 220 and the plurality of upper sheet patterns NS2. The gate insulating film 130 may be disposed on the first liner film 292. The gate insulating film 130 may be disposed between the first metal pattern 120 and the lower source/drain pattern 150, and between the second metal pattern 220 and the upper source/drain pattern 250.

In some implementations, the gate insulating film 130 may include a plurality of films. For example, the gate insulating film 130 may include an interfacial insulating film and a high-k insulating film. The interfacial insulating film may include, for example, silicon oxide. The high-k insulating film may include a high-k material having a dielectric constant greater than that of the interfacial insulating film. The high-k insulating film may include at least one of boron nitride, hafnium oxide, hafnium silicon oxide, hafnium aluminum oxide, lanthanum oxide, lanthanum aluminum oxide, zirconium oxide, zirconium silicon oxide, tantalum oxide, titanium oxide, barium strontium titanate, barium titanate, strontium titanate, yttrium oxide, aluminum oxide, lead scandium tantalate, or lead zinc niobate.

The lower gate contact 125 may be disposed on the gate electrode structure GS. For example, the lower gate contact 125 may be disposed under the gate electrode structure GS and may be connected to the gate electrode structure GS. For example, the lower gate contact 125 may be connected to the first metal pattern 120. In some implementations, the lower gate contact 125 may extend through a lower surface of the first metal pattern 120. One end of the lower gate contact 125 may be disposed in the first metal pattern 120.

The lower gate contact 125 may overlap each of the plurality of lower sheet patterns NS1 and the plurality of upper sheet patterns NS2 in the third direction D3. The lower gate contact 125 may be aligned with the plurality of lower sheet patterns NS1 and the plurality of upper sheet patterns NS2 in the third direction D3. For example, the plurality of lower sheet patterns NS1 and the plurality of upper sheet patterns NS2 may be sequentially disposed on the lower gate contact 125.

The width of the lower gate contact 125 in the second direction D2 may not be constant. For example, the width of the lower gate contact 125 in the second direction D2 may increase as it becomes further away from the plurality of lower sheet patterns NS1. In another example, the width of the lower gate contact 125 in the second direction D2 may remain constant and then increase as it becomes further away from the plurality of lower sheet patterns NS1.

The lower gate contact 125 may include a first side surface 125_SS1, a second side surface 125_SS2, a third side surface 125_SS3, and a fourth side surface 125_SS4. The first side surface 125_SS1 of the lower gate contact 125 may face the second side surface 125_SS2 in the second direction D2. The third side surface 125_SS3 of the lower gate contact 125 may face the fourth side surface 125_SS4 in the first direction D1.

As shown in FIG. 4, the first side surface 125_SS1 and the second side surface 125_SS2 of the lower gate contact 125 may include a first portion P1 and a second portion P2. Since the description of the second side surface 125_SS2 of the lower gate contact 125 is identical to the description of the first side surface 125_SS1, the following description focuses on the first side surface 125_SS1. The first portion P1 of the first side surface 125_SS1 may have a first slope, and the second portion P2 of the first side surface 125_SS1 may have a second slope. The first slope may differ from the second slope. For example, the first slope may be greater than the second slope.

In some implementations, each of the first side surface 125_SS1 and the second side surface 125_SS2 of the lower gate contact 125 may have a constant slope. As shown in FIG. 5, in terms of cross-section, each of the first side surface 125_SS1 and the second side surface 125_SS2 of the lower gate contact 125 may have a linear shape.

The lower gate contact 125 may include a gate contact barrier film 122 and a gate contact filling film 124. The gate contact barrier film 122 may define side surfaces of the lower gate contact 125. The gate contact filling film 124 may be disposed in the gate contact barrier film 122.

The gate contact barrier film 122 may include, for example, one of tantalum (Ta), tantalum nitride (TaN), titanium (Ti), titanium nitride (TiN), ruthenium (Ru), cobalt (Co), nickel (Ni), nickel boride (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). The gate contact filling film 124 may include, for example, one of aluminum (Al), tungsten (W), cobalt (Co), ruthenium (Ru), and molybdenum (Mo), although the present disclosure is not limited thereto.

The first liner film 292 may surround side surfaces of the lower gate contact 125. The first liner film 292 may be disposed on the side surfaces of the lower gate contact 125. For example, the first liner film 292 may be disposed on the first side surface 125_SS1, the second side surface 125_SS2, the third side surface 125_SS3, and the fourth side surface 125_SS4 of the lower gate contact 125. The first liner film 292 may be disposed on parts of the first portion P1 and the second portion P2 of the first side surface 125_SS1. In some implementations, the first liner film 292 may contact the first through fourth side surfaces 125_SS1-125_SS4 of the lower gate contact 125.

An upper surface 292_US of the first liner film 292 may be disposed at a lower vertical level than an upper surface 125_US of the lower gate contact 125. In the present disclosure, a vertical level represents a vertical level in the third direction D3. The vertical level may represent a distance in the third direction D3 from a reference level to a surface of a specific structure. The reference level may correspond to a vertical level of an upper or lower surface of an arbitrary structure having a planar surface. One end of the lower gate contact 125 may protrude in the third direction D3 from the upper surface 292_US of the first liner film 292. The lower gate contact 125 may extend through the upper surface 292_US of the first liner film 292. The lower gate contact 125 may extend through the gate insulating film 130 disposed on the upper surface 292_US of the first liner film 292.

The gate insulating film 130 may be disposed between the first liner film 292 and the gate electrode structure GS. The gate insulating film 130 may be disposed on the first liner film 292. For example, the gate insulating film 130 may be disposed on the upper surface 292_US and both side surfaces in the second direction D2 of the first liner film 292. The gate insulating film 130 disposed on the upper surface 292_US of the first liner film 292 may contact the lower gate contact 125.

The width of the first liner film 292 in the second direction D2 may increase as it becomes further away from the plurality of lower sheet patterns NS1. The width of the first liner film 292 in the second direction D2 may be equal to or greater than the width of the plurality of lower sheet patterns NS1 in the second direction D2. For example, a width W1 of the upper surface 292_US of the first liner film 292 in the second direction D2 may be equal to or greater than a width W2 of a lower surface of the second lower sheet pattern NS1_2 in the second direction D2.

The first liner film 292 may include a material different from the plurality of lower sheet patterns NS1. The first liner film 292 may include an insulating material. For example, the first liner film 292 may include one of silicon nitride (SiN), silicon oxynitride (SiON), silicon carbonitride (SiCN), and silicon oxycarbonitride (SiOCN). However, the present disclosure is not limited thereto.

The lower source/drain pattern 150 may be disposed on the active region AP. The lower source/drain pattern 150 may be disposed on side surfaces of the plurality of lower sheet patterns NS1. The lower source/drain pattern 150 may be connected to the plurality of lower sheet patterns NS1. A portion of a side surface of the lower source/drain pattern 150 may contact the lower sheet pattern NS1, and another portion may contact the gate insulating film 130. The lower source/drain pattern 150 may be disposed on one side of the gate electrode structure GS.

The lower source/drain pattern 150 may be an epitaxial pattern formed by a selective epitaxial growth process using the plurality of lower sheet patterns NS1 as seeds. The lower source/drain pattern 150 may function as a source or drain of a transistor that uses the plurality of lower sheet patterns NS1 as channel regions.

An insulating capping layer 205 may be disposed on the lower source/drain pattern 150. The insulating capping layer 205 may cover an upper surface of the lower source/drain pattern 150. The description of the material of the insulating capping layer 205 may be identical to the description of the material of an etch-stop film 285.

The middle interlayer insulating film 200 may be disposed on the insulating capping layer 205. The middle interlayer insulating film 200 may be disposed between the insulating capping layer 205 and the upper source/drain pattern 250. The middle interlayer insulating film 200 may be disposed on a side surface of the middle insulating pattern 202. In some implementations, a portion of the middle interlayer insulating film 200 may overlap the middle insulating pattern 202 in the first direction D1. The middle interlayer insulating film 200 may include an insulating material. The description of the material of the middle interlayer insulating film 200 may be identical to the description of the material of an upper interlayer insulating film 280.

The upper source/drain pattern 250 may be disposed on the active region AP. The upper source/drain pattern 250 may be disposed on the middle interlayer insulating film 200. The upper source/drain pattern 250 may be disposed on side surfaces of the plurality of upper sheet patterns NS2. The upper source/drain pattern 250 may be connected to the plurality of upper sheet patterns NS2. A portion of a side surface of the upper source/drain pattern 250 may contact the upper sheet pattern NS2, and another portion may contact the gate insulating film 130. The upper source/drain pattern 250 may be disposed on one side of the gate electrode structure GS. The upper source/drain pattern 250 may overlap the lower source/drain pattern 150 in the third direction D3.

The upper source/drain pattern 250 may be an epitaxial pattern formed by a selective epitaxial growth process using the plurality of upper sheet patterns NS2 as seeds. The upper source/drain pattern 250 may function as a source or drain of a transistor that uses the plurality of upper sheet patterns NS2 as channel regions.

Each of the lower source/drain pattern 150 and the upper source/drain pattern 250 may include a semiconductor material. For example, each of the lower source/drain pattern 150 and the upper source/drain pattern 250 may include elemental semiconductor silicon (Si) or germanium (Ge). Each of the lower source/drain pattern 150 and the upper source/drain pattern 250 may also include a binary or ternary IV-group compound including at least two of carbon (C), silicon (Si), germanium (Ge), or tin (Sn) or a IV-group doped compound thereof. For example, each of the lower source/drain pattern 150 and the upper source/drain pattern 250 may include silicon (Si), silicon germanium (SiGe), germanium (Ge), or silicon carbide (SiC), although the present disclosure is not limited thereto.

Each of the lower source/drain pattern 150 and the upper source/drain pattern 250 may include a dopant doped in the semiconductor material. The dopant may include at least one of boron (B), phosphorus (P), carbon (C), arsenic (As), antimony (Sb), bismuth (Bi), or oxygen (O), without limitation. In some implementations, the lower source/drain pattern 150 and the upper source/drain pattern 250 may include dopants having different conductivity types.

Each of the lower source/drain pattern 150 and the upper source/drain pattern 250 is illustrated as a single film for convenience of description, but the present disclosure is not limited thereto. In some implementations, each of the lower source/drain pattern 150 and the upper source/drain pattern 250 may include a plurality of films including different materials. In some implementations, each of the lower source/drain pattern 150 and the upper source/drain pattern 250 may include the same material and a plurality of layers having different concentrations of the constituent material.

The lower source/drain contact 160 may be disposed on the lower source/drain pattern 150. The lower source/drain contact 160 may be disposed under the lower source/drain pattern 150. The lower source/drain contact 160 may extend through a lower surface of the lower source/drain pattern 150. One end of the lower source/drain contact 160 may be disposed in the lower source/drain pattern 150. For example, an upper surface of the lower source/drain contact 160 may be disposed in the lower source/drain pattern 150. The lower source/drain contact 160 may be electrically connected to the lower source/drain pattern 150.

The lower source/drain contact 160 may be aligned with the lower gate contact 125 in the first direction D1. The lower source/drain contact 160 may overlap the lower gate contact 125 in the first direction D1. The first liner film 292 and the second liner film 294 may be disposed between the lower source/drain contact 160 and the lower gate contact 125.

The lower source/drain contact 160 may include a lower source/drain contact barrier film 162 and a lower source/drain contact filling film 164. The lower source/drain contact barrier film 162 may define side and upper surfaces of the lower source/drain contact 160. The lower source/drain contact filling film 164 may be disposed in the lower source/drain contact barrier film 162.

The lower source/drain contact barrier film 162 may include, for example, one of tantalum (Ta), tantalum nitride (TaN), titanium (Ti), titanium nitride (TiN), ruthenium (Ru), cobalt (Co), nickel (Ni), nickel boride (NiB), tungsten (W), tungsten nitride (WN), tungsten carbonitride (WCN), zirconium (Zr), zirconium nitride (ZrN), vanadium (V), vanadium nitride (VN), niobium (Nb), niobium nitride (NbN), platinum (Pt), iridium (Ir), and rhodium (Rh). The lower source/drain contact filling film 164 may include, for example, one of aluminum (Al), tungsten (W), cobalt (Co), ruthenium (Ru), and molybdenum (Mo), although the present disclosure is not limited thereto.

The second liner film 294 may be disposed on a lower surface of the lower source/drain pattern 150. The second liner film 294 may be disposed on a side surface of the lower source/drain contact 160. For example, the second liner film 294 may surround the side surface of the lower source/drain contact 160. In some implementations, the second liner film 294 may contact the first liner film 292, although the present disclosure is not limited thereto.

The second liner film 294 may include an insulating material. For example, the second liner film 294 may include one of silicon nitride (SiN), silicon oxynitride (SiON), silicon carbonitride (SiCN), and silicon oxycarbonitride (SiOCN), although the present disclosure is not limited thereto. In some implementations, the first liner film 292 and the second liner film 294 may include the same material. In some implementations, the first liner film 292 and the second liner film 294 may include different materials.

When the first liner film 292 and the second liner film 294 include the same material, a boundary between the first liner film 292 and the second liner film 294 may be indistinguishable. However, the present disclosure is not limited thereto. For example, a silicon oxide film may be formed between the first liner film 292 and the second liner film 294, so the boundary between the first liner film 292 and the second liner film 294 may be distinguishable.

The upper source/drain contact 260 may be disposed on the upper source/drain pattern 250. The upper source/drain contact 260 may extend through the upper interlayer insulating film 280, the etch-stop film 285, and an upper surface of the upper source/drain pattern 250. One end of the upper source/drain contact 260 may be disposed in the upper source/drain pattern 250. For example, the upper source/drain contact 260 may be electrically connected to the upper source/drain pattern 250.

The upper source/drain contact 260 may include an upper source/drain contact barrier film 262 and an upper source/drain contact filling film 264. The descriptions of the materials of the upper source/drain contact barrier film 262 and the upper source/drain contact filling film 264 may be identical to the descriptions of the materials of the lower source/drain contact barrier film 162 and the lower source/drain contact filling film 164, respectively.

The gate spacer 275 may be disposed on a side surface of the gate electrode structure GS. For example, the gate spacer 275 may be disposed on a side surface of the second metal pattern 220. The gate spacer 275 may be disposed on both side surfaces of the second metal pattern 220 disposed on the first upper sheet pattern NS2_1. The gate spacer 275 may extend along a side surface of the gate electrode structure GS. The gate insulating film 130 may be disposed between the gate spacer 275 and the gate electrode structure GS. For example, the gate insulating film 130 may extend along both side surfaces of the gate spacer 275.

The gate spacer 275 may include, for example, at least one of silicon nitride (SiN), silicon oxynitride (SiON), silicon oxide (SiO₂), silicon oxycarbonitride (SiOCN), silicon boron nitride (SiBN), silicon oxyboron nitride (SiOBN), silicon oxycarbon (SiOC), or a combination thereof. Although the gate spacer 275 is illustrated as a single film, the present disclosure is not limited thereto.

The gate capping pattern 270 may be disposed on upper surfaces of the gate electrode structure GS, the gate spacer 275, and the gate separation structure 310. The gate capping pattern 270 may cover the upper surfaces of the gate electrode structure GS and the gate separation structure 310. Although the gate capping pattern 270 is illustrated as contacting an upper surface of the gate spacer 275, the present disclosure is not limited thereto. For example, the gate capping pattern 270 may be disposed between a pair of gate spacers 275 and may contact a side surface of the gate spacer 275.

The gate capping pattern 270 may include at least one of silicon nitride (SiN), silicon oxynitride (SiON), silicon carbonitride (SiCN), silicon oxycarbonitride (SiOCN), or a combination thereof. The gate capping pattern 270 may include a material having an etch selectivity with respect to the upper interlayer insulating film 280.

The upper interlayer insulating film 280 may be disposed on the upper source/drain pattern 250. An etch-stop film 285 may be disposed between the upper interlayer insulating film 280 and the upper source/drain pattern 250. The upper interlayer insulating film 280 may be disposed in the etch-stop film 285.

The upper interlayer insulating film 280 may include at least one of silicon oxide (SiO), silicon nitride (SiN), silicon oxynitride (SiON), or a low-k material. The low-k material may include, for example, fluorinated tetraethyl orthosilicate (FTEOS), hydrogen silsesquioxane (HSQ), bis-benzocyclobutene (BCB), tetramethyl orthosilicate (TMOS), octamethylcyclotetrasiloxane (OMCTS), hexamethyldisiloxane (HMDS), trimethylsilyl borate (TMSB), diacetoxyditert-butoxysiloxane (DADBS), trimethylsilyl phosphate (TMSP), polytetrafluoroethylene (PTFE), TOSZ (Tonen Silazen), FSG (fluorosilicate glass), polypropylene-oxide-based polyimide nanofoams, carbon-doped silicon oxide (CDO), organosilicate glass (OSG), SiLK, amorphous fluorinated carbon, silica aerogels, silica xerogels, mesoporous silica, or combinations thereof, although the present disclosure is not limited thereto.

The etch-stop film 285 may be disposed between the upper interlayer insulating film 280 and the upper source/drain pattern 250. The etch-stop film 285 may cover an upper surface of the upper source/drain pattern 250. The etch-stop film 285 may include at least one of silicon nitride (SiN), silicon oxide (SiO), silicon oxynitride (SiON), silicon oxycarbonitride (SiOCN), silicon boron nitride (SiBN), silicon oxyboron nitride (SiOBN), silicon oxycarbon (SiOC), or a combination thereof.

The gate separation structure 310 may be disposed on a lower surface of the gate capping pattern 270. The gate separation structure 310 may extend in the first direction D1 and the third direction D3. The gate separation structure 310 may be disposed on a side surface of the gate electrode structure GS. The gate separation structure 310 may separate the gate electrode structure GS. The width of the gate separation structure 310 in the second direction D2 may increase as it becomes further away from the gate capping pattern 270.

A portion of the gate separation structure 310 may be disposed on a side surface of the first liner film 292. In some implementations, a portion of the gate separation structure 310 may contact the first liner film 292. The gate electrode structure GS may be disposed between the gate separation structure 310 and the first liner film 292. For example, the first metal pattern 120 may be disposed between the gate separation structure 310 and the first liner film 292.

In a semiconductor device, the gate electrode structure GS requires a width not less than a predetermined size in order to form a gate contact 125. In a semiconductor device according to some implementations of the present disclosure, the lower gate contact 125 may overlap the plurality of lower sheet patterns NS1 and the plurality of upper sheet patterns NS2 in the third direction D3. By disposing the lower gate contact 125 so as to overlap the sheet patterns NS1 and NS2 in the third direction D3, the width of the gate electrode structure GS in the second direction D2 may be reduced. The area of the gate electrode structure GS may thereby be reduced, improving the integration density of the semiconductor device. In addition, as the area of the gate electrode structure GS is reduced, parasitic capacitance may be reduced, and electrical characteristics of the semiconductor device may be enhanced.

The gate separation structure 310 may include an insulating liner film 312 and an insulating filling film 314. The insulating liner film 312 may define side and upper surfaces of the gate separation structure 310. The insulating filling film 314 may be disposed in the insulating liner film 312. The insulating liner film 312 may include, for example, one of silicon nitride (SiN), silicon oxynitride (SiON), silicon oxycarbonitride (SiOCN), silicon boron nitride (SiBN), silicon oxyboron nitride (SiOBN), and silicon carbonitride (SiCN). The insulating filling film 314 may include, for example, at least one of silicon oxide (SiO₂), silicon oxynitride (SiON), silicon oxycarbonitride (SiOCN), silicon oxyboron nitride (SiOBN), silicon oxycarbon (SiOC), or a combination thereof.

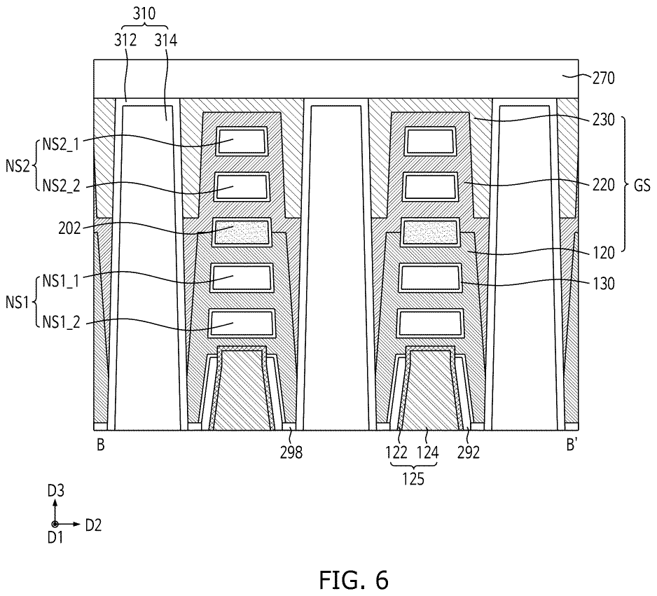

FIG. 6 is a view illustrating a semiconductor device according to some implementations of the present disclosure. For convenience, elements different from those described with reference to FIGS. 1-5 are mainly described.

Referring to FIG. 6, a semiconductor device according to some implementations may include a lower spacer 298.

The lower spacer 298 may be disposed between the first liner film 292 and the gate separation structure 310. The gate separation structure 310 may be disposed on a first side surface of the lower spacer 298. The first liner film 292 may be disposed on a second side surface of the lower spacer 298. An upper surface of the lower spacer 298 may contact the gate electrode structure GS and the gate insulating film 130. The lower spacer 298 may space apart the gate electrode structure GS and the first liner film 292.

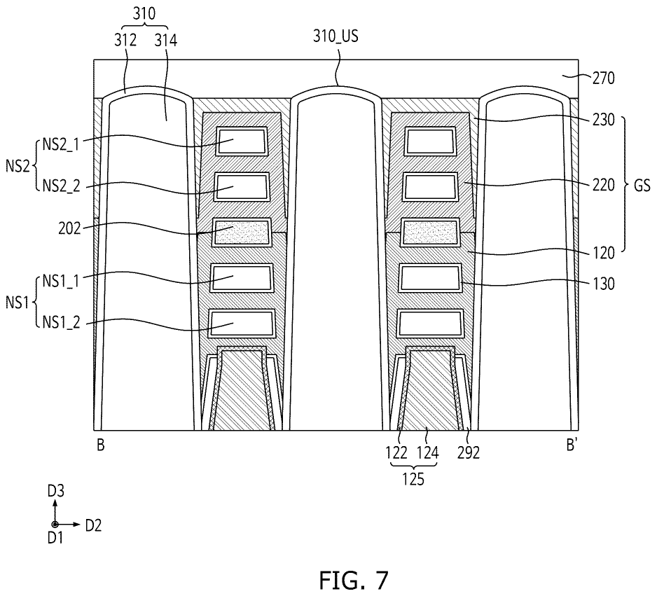

FIG. 7 is a view illustrating a semiconductor device according to some implementations of the present disclosure. For convenience, elements different from those described with reference to FIGS. 1-5 are mainly described.

Referring to FIG. 7, in a semiconductor device according to some implementations, an upper surface 310_US of the gate separation structure 310 may include a convex curved surface. The upper surface 310_US of the gate separation structure 310 may be disposed at a higher vertical level than an upper surface of the gate electrode structure GS.

The gate capping pattern 270 may be disposed on the upper surface 310_US of the gate separation structure 310. The gate capping pattern 270 may include a concave shape corresponding to the upper surface 310_US of the gate separation structure 310.

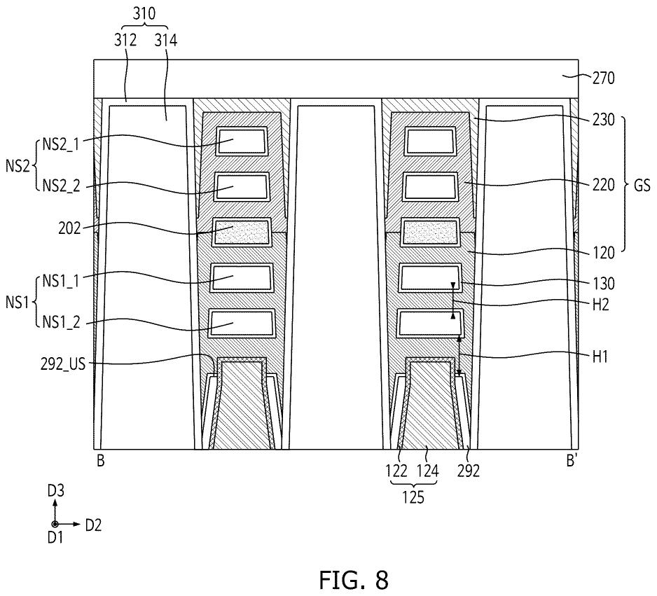

FIG. 8 is a view illustrating a semiconductor device according to some implementations of the present disclosure. For convenience, elements different from those described with reference to FIGS. 1-5 are mainly described.

Referring to FIG. 8, in a semiconductor device according to some implementations, a distance between the first liner film 292 and the second lower sheet pattern NS1_2 may differ from a distance between the second lower sheet pattern NS1_2 and the first lower sheet pattern NS1_1. For example, a distance H1 from the upper surface 292_US of the first liner film 292 to a lower surface of the second lower sheet pattern NS1_2 may be greater than a distance H2 from an upper surface of the second lower sheet pattern NS1_2 to a lower surface of the first lower sheet pattern NS1_1.

An upper surface of the lower gate contact 125 may be disposed between the first liner film 292 and the second lower sheet pattern NS1_2. In a semiconductor device according to some implementations, by forming the distance H1 from the upper surface 292_US of the first liner film 292 to the lower surface of the second lower sheet pattern NS1_2 larger, a process margin for forming the lower gate contact 125 may be improved.

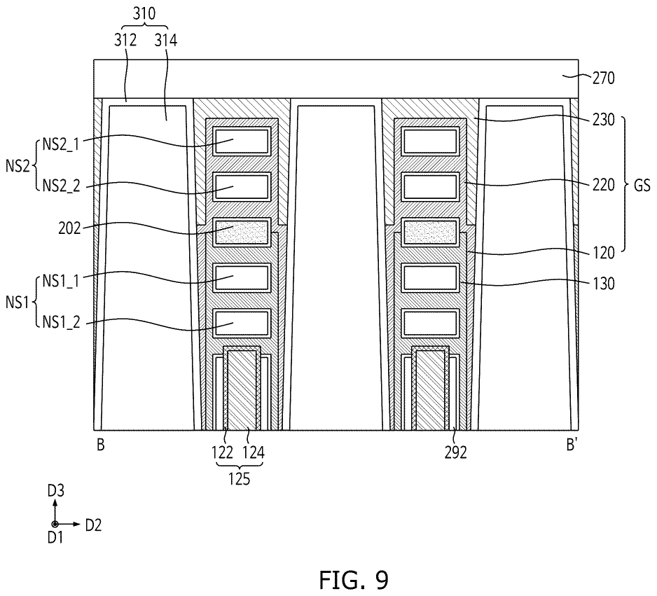

FIG. 9 is a view illustrating a semiconductor device according to some implementations of the present disclosure. For convenience, elements different from those described with reference to FIGS. 1-5 are mainly described.

Referring to FIG. 9, in a semiconductor device according to some implementations, widths of the first liner film 292, the plurality of lower sheet patterns NS1, and the plurality of upper sheet patterns NS2 in the second direction D2 may be constant. In some implementations, the width of the first liner film 292 in the second direction D2 and the widths of the plurality of lower sheet patterns NS1 and the plurality of upper sheet patterns NS2 in the second direction D2 may be identical.

The width of the lower gate contact 125 in the second direction D2 may be constant. The width of the lower gate contact 125 in the second direction D2 may be smaller than the width of the plurality of lower sheet patterns NS1 in the second direction D2.

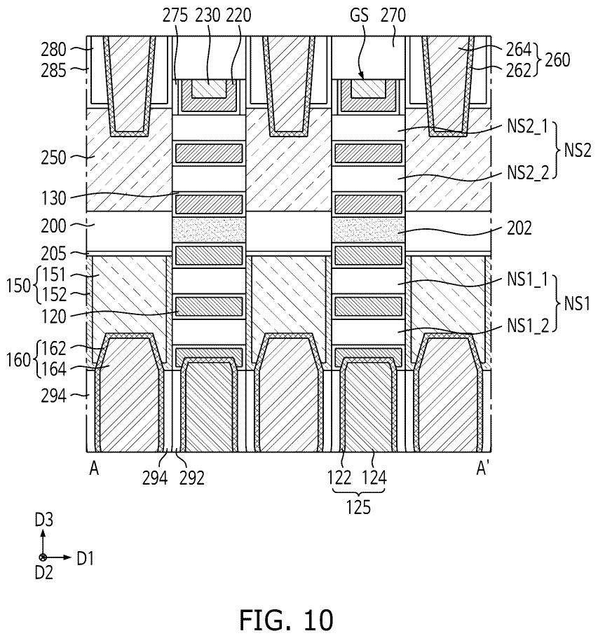

FIG. 10 is a view illustrating a semiconductor device according to some implementations of the present disclosure. For convenience, elements different from those described with reference to FIGS. 1-5 are mainly described.

Referring to FIG. 10, in a semiconductor device according to some implementations, the lower source/drain pattern 150 may include a lower source/drain liner film 152 and a lower source/drain filling film 151.

The lower source/drain pattern 150 may be disposed in a lower source/drain trench. The lower source/drain liner film 152 may extend along sidewalls of the lower source/drain trench. The lower source/drain liner film 152 may define sidewalls of the lower source/drain pattern 150. The lower source/drain liner film 152 may extend along side surfaces of the plurality of lower sheet patterns NS1. The lower source/drain liner film 152 may contact side surfaces of the plurality of lower sheet patterns NS1 and the gate insulating film 130. The gate insulating film 130 may be disposed between the lower source/drain liner film 152 and the first metal pattern 120.

The lower source/drain filling film 151 may be disposed in the lower source/drain liner film 152. Although only a single layer of the lower source/drain filling film 151 is illustrated, the present disclosure is not limited thereto; the lower source/drain filling film 151 may include a plurality of layers.

In some implementations, the lower source/drain liner film 152 and the lower source/drain filling film 151 may include the same material, with different concentrations of the constituent material. However, the present disclosure is not limited thereto. For example, the lower source/drain liner film 152 and the lower source/drain filling film 151 may include different materials.

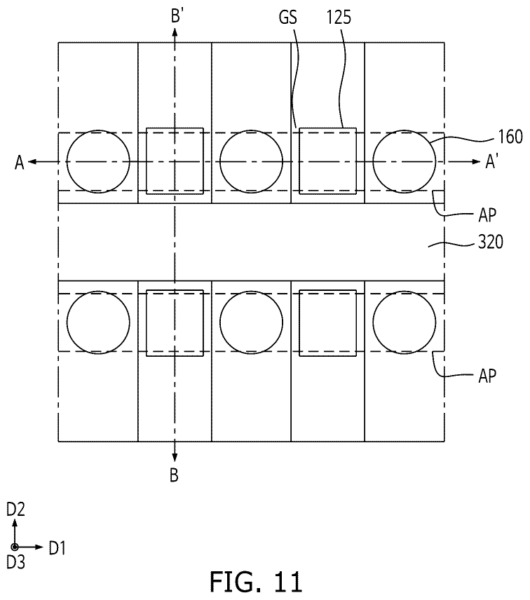

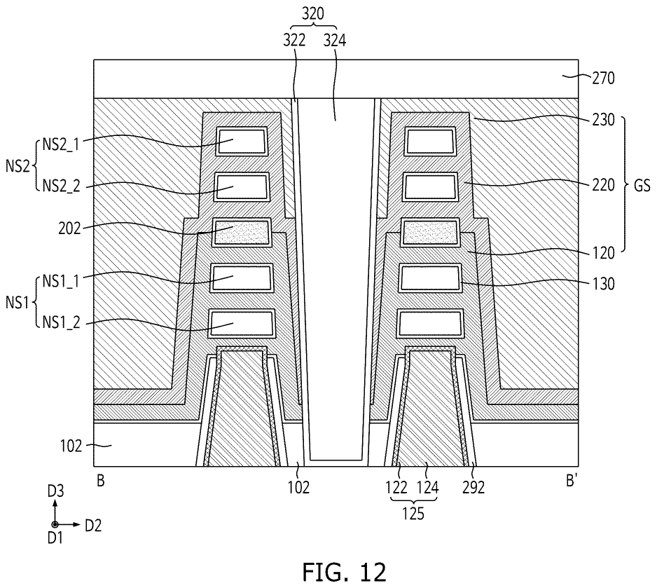

FIGS. 11 and 12 are views illustrating a semiconductor device according to some implementations of the present disclosure. For reference, FIG. 11 is a plan view illustrating a semiconductor device according to some implementations of the present disclosure, and FIG. 12 is a cross-sectional view illustrating a cut taken along line B-B′ of FIG. 11. A cross-sectional view illustrating a cut taken along line A-A′ of FIG. 11 may be similar to FIG. 2.

Referring to FIGS. 11 and 12, a semiconductor device according to some implementations may include a device isolation film 102.

The device isolation film 102 may be disposed under the gate electrode structure GS, and the gate insulating film 130 may be disposed on an upper surface of the device isolation film 102. The device isolation film 102 may be disposed on a side surface of the first liner film 292. The device isolation film 102 may have a shallow-trench-isolation (STI) structure having superior device isolation characteristics.

The lower gate contact 125 may be disposed between device isolation films 102 adjacent in the second direction D2. In some implementations, a lower surface of the lower gate contact 125 may be disposed on the same plane as a lower surface of the device isolation film 102.

The device isolation film 102 may include at least one of a silicon oxide film, a silicon nitride film, and a silicon oxynitride film, although the present disclosure is not limited thereto. Although the device isolation film 102 is illustrated as a single insulating film, the present disclosure is not limited thereto.

The gate separation structure 320 may separate the gate electrode structure GS. The gate separation structure 320 may extend into the gate electrode structure GS and the device isolation film 102. The gate separation structure 320 may be spaced apart from the active region AP in the second direction D2. The gate separation structure 320 may be disposed on a lower surface of the gate capping pattern 270. The gate separation structure 320 may extend in the first direction D1 and the third direction D3. A width of the gate separation structure 320 in the second direction D2 may decrease as the gate separation structure 320 becomes further away from the gate capping pattern 270.

The gate separation structure 320 may include an insulating liner film 322 and an insulating filling film 324. The insulating liner film 322 may define side surfaces of the gate separation structure 320. The insulating filling film 324 may be disposed in the insulating liner film 322. The insulating liner film 322 may include, for example, one of silicon nitride (SiN), silicon oxynitride (SiON), silicon oxycarbonitride (SiOCN), silicon boron nitride (SiBN), silicon oxyboron nitride (SiOBN), and silicon carbonitride (SiCN). The insulating filling film 324 may include at least one of silicon oxide (SiO₂), silicon oxynitride (SiON), silicon oxycarbonitride (SiOCN), silicon oxyboron nitride (SiOBN), silicon oxycarbon (SiOC), or a combination thereof.

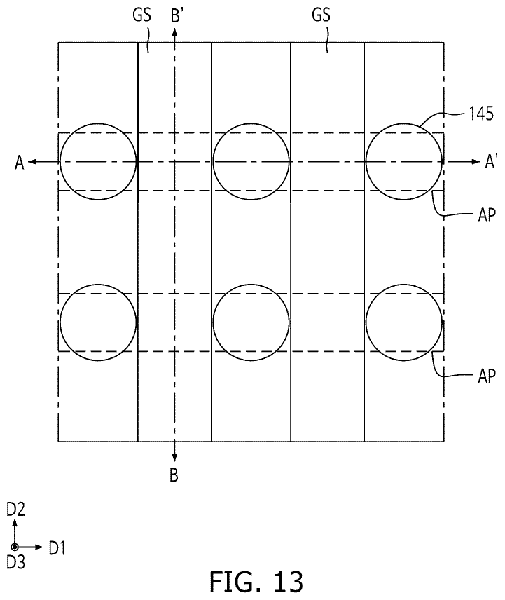

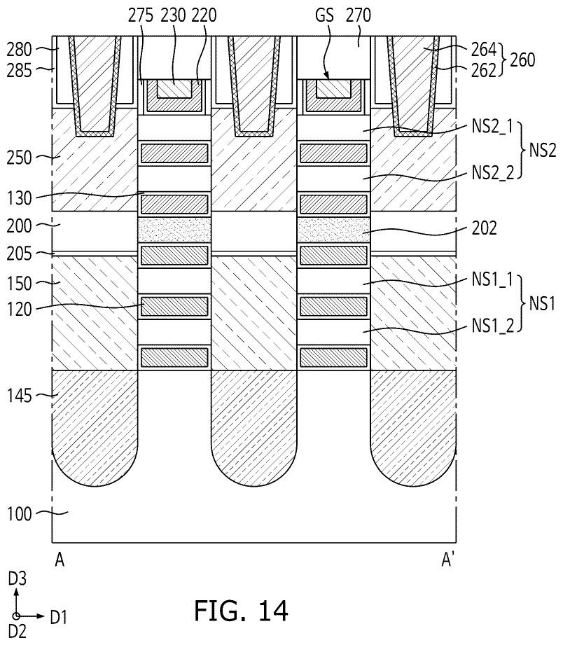

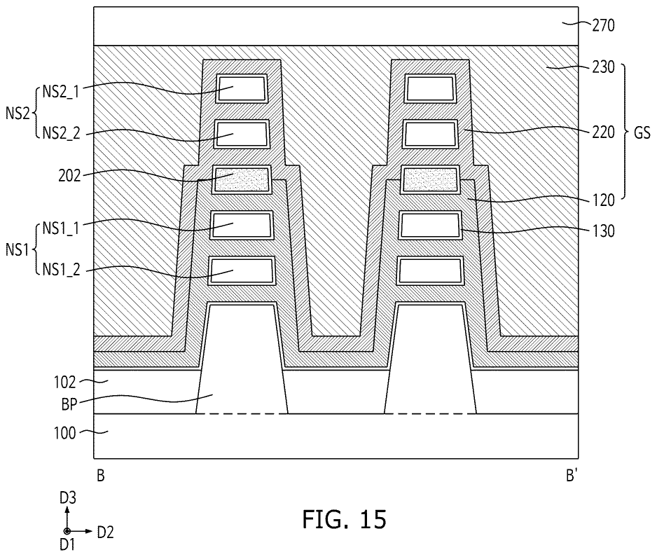

FIGS. 13-32 are views illustrating a method of manufacturing a semiconductor device according to some implementations of the present disclosure. For reference, FIG. 13 is a plan view illustrating a semiconductor manufacturing method according to some implementations. FIGS. 14, 16, 18, 20, 22, 25, 27, 29, and 31 are cross-sectional views illustrating cuts taken along line A-A′ of FIG. 13. FIGS. 15, 17, 19, 21, 23, 24, 26, 28, 30, and 32 are cross-sectional views illustrating cuts taken along line B-B′ of FIG. 13. For convenience, elements identical to those described with reference to FIGS. 1-5 are briefly described or omitted.

Referring to FIGS. 13-15, on a substrate 100, the plurality of lower sheet patterns NS1, the plurality of upper sheet patterns NS2, the gate electrode structure GS, the gate insulating film 130, the middle insulating pattern 202, a pre-semiconductor pattern 145, the lower source/drain pattern 150, the upper source/drain pattern 250, the insulating capping layer 205, the middle interlayer insulating film 200, the upper source/drain contact 260, the gate spacer 275, the gate capping pattern 270, the upper interlayer insulating film 280, and the etch-stop film 285 may be formed.

The substrate 100 may be bulk silicon or silicon-on-insulator (SOI). Alternatively, the substrate 100 may include silicon germanium (SiGe), silicon germanium-on-insulator (SGOI), indium antimonide, lead telluride compounds, indium arsenide, indium phosphide, gallium arsenide, or gallium antimonide, but is not limited thereto.

The substrate 100 may include a lower pattern BP. The lower pattern BP may overlap the plurality of lower sheet patterns NS1 and the plurality of upper sheet patterns NS2 in the third direction D3. In some implementations, the lower pattern BP may be formed by removing a portion of the substrate 100, although the present disclosure is not limited thereto. A device isolation film 102 may be disposed between lower patterns BP adjacent in the second direction D2.

The plurality of lower sheet patterns NS1 and the plurality of upper sheet patterns NS2 spaced apart from each other in the third direction D3 may be formed on the lower pattern BP of the substrate 100. Subsequently, the pre-semiconductor pattern 145, the lower source/drain pattern 150, and the upper source/drain pattern 250 may be formed on the substrate 100. The pre-semiconductor pattern 145 may be disposed on the substrate 100. The pre-semiconductor pattern 145 may overlap the substrate 100 in the first direction D1. The pre-semiconductor pattern 145 may include a semiconductor material. Then, the gate insulating film 130 may be formed and the gate electrode structure GS may be formed.

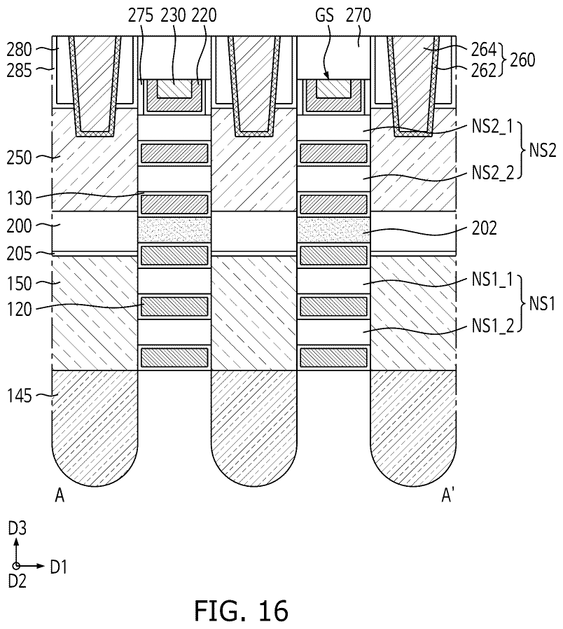

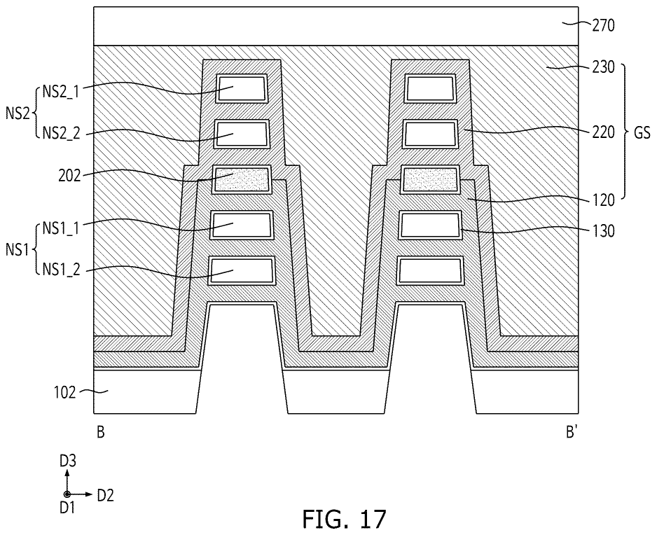

Referring to FIGS. 16 and 17, the substrate 100 may be removed, so the pre-semiconductor pattern 145, the device isolation film 102, and the gate insulating film 130 may be exposed. For example, the lower pattern BP of the substrate 100 may be removed so that a side surface of the device isolation film 102 and the gate insulating film 130 are exposed.

In some implementations, before the substrate 100 is removed, the semiconductor device may be flipped. For example, the semiconductor device shown in FIGS. 14 and 15 may be rotated by 180 degrees so that the substrate 100 is disposed on top. Then the substrate 100 may be removed by an etching process.

In some implementations, the step of removing the substrate 100 may include a chemical-mechanical-polishing (CMP) process. For example, a portion of the substrate 100 may be removed by the CMP process, and the remaining substrate 100 may be removed by an etching process.

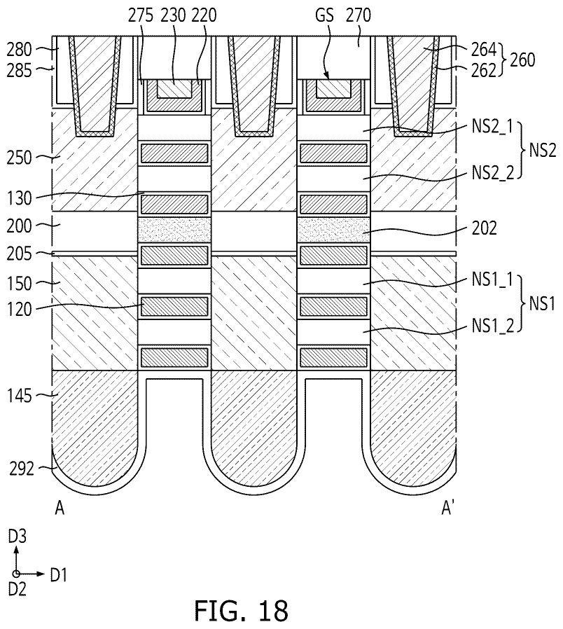

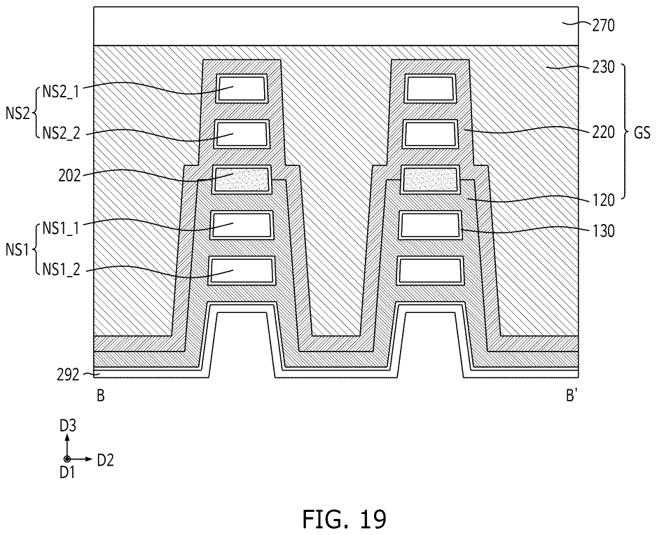

Referring to FIGS. 18 and 19, the device isolation film 102 shown in FIG. 17 may be removed, and the first liner film 292 may be formed. For example, the device isolation film 102 may be removed so as to expose the gate insulating film 130. Then, the first liner film 292 may be formed on the pre-semiconductor pattern 145 and the gate insulating film 130. The first liner film 292 may extend along the gate insulating film 130 exposed by removal of the lower pattern BP (see FIG. 15) and the device isolation film 102. The first liner film 292 may extend along a lower surface and a side surface of the pre-semiconductor pattern 145. In some implementations, the first liner film 292 may be formed conformally, although the present disclosure is not limited thereto.

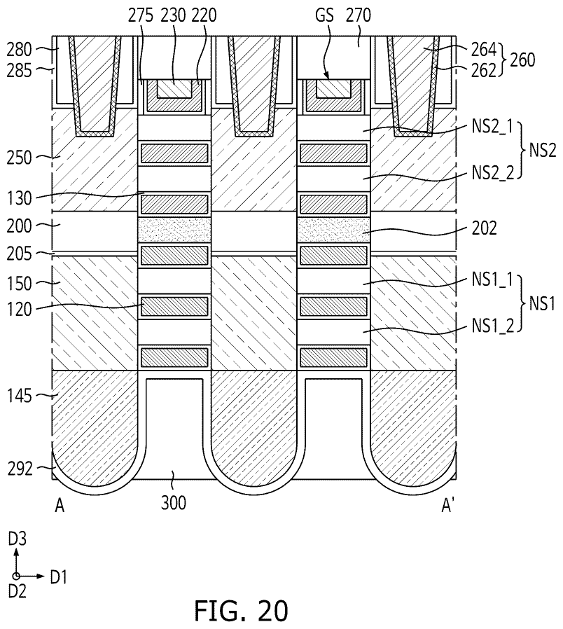

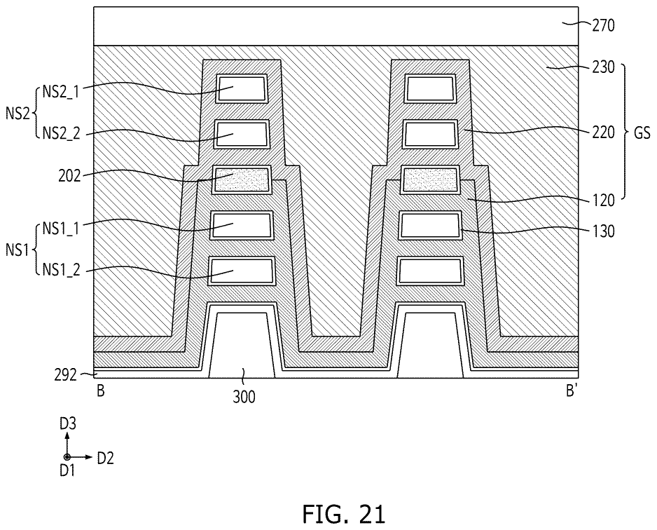

Referring to FIGS. 20 and 21, a sacrificial insulating pattern 300 may be formed on the first liner film 292. For example, an insulating material may be deposited on the first liner film 292 so as to cover the first liner film 292. Then a portion of the insulating material may be removed to form the sacrificial insulating pattern 300. For example, a portion of the insulating material may be removed by a CMP process. The sacrificial insulating pattern 300 may not cover a portion of the gate insulating film 130. The sacrificial insulating pattern 300 may expose a portion of the gate insulating film 130.

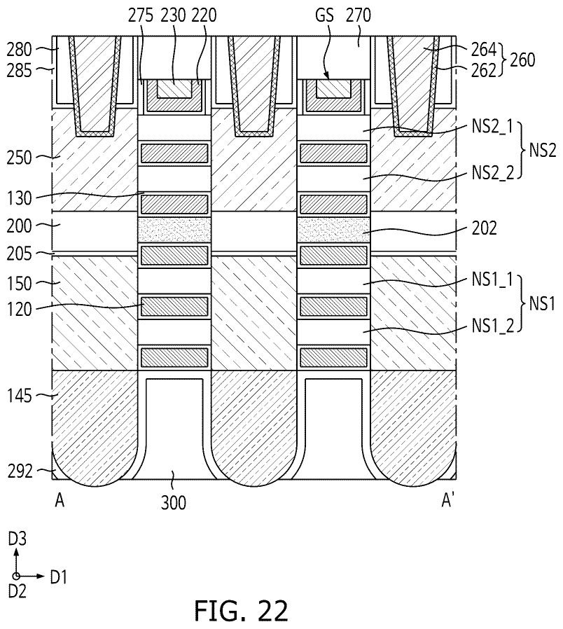

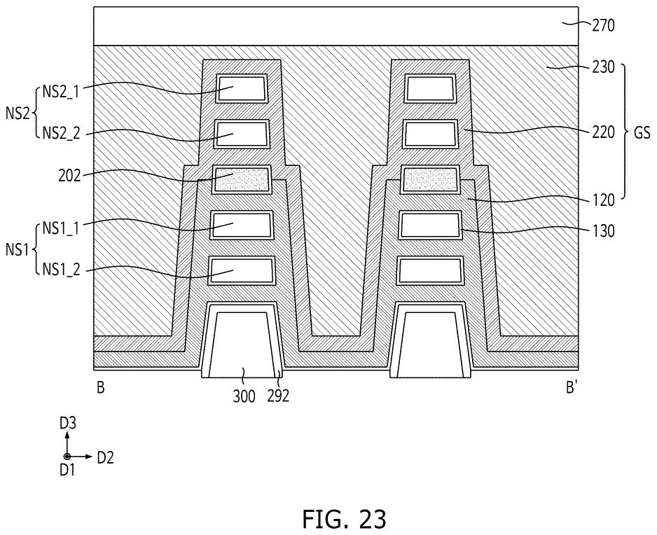

Referring to FIGS. 22 and 23, the exposed portion of the first liner film 292, by the sacrificial insulating pattern 300, may be removed. A portion of the first liner film 292 may be removed to expose the pre-semiconductor pattern 145 and the gate insulating film 130. The first liner film 292 may be formed on the sacrificial insulating pattern 300. The first liner film 292 may surround side surfaces of the sacrificial insulating pattern 300.

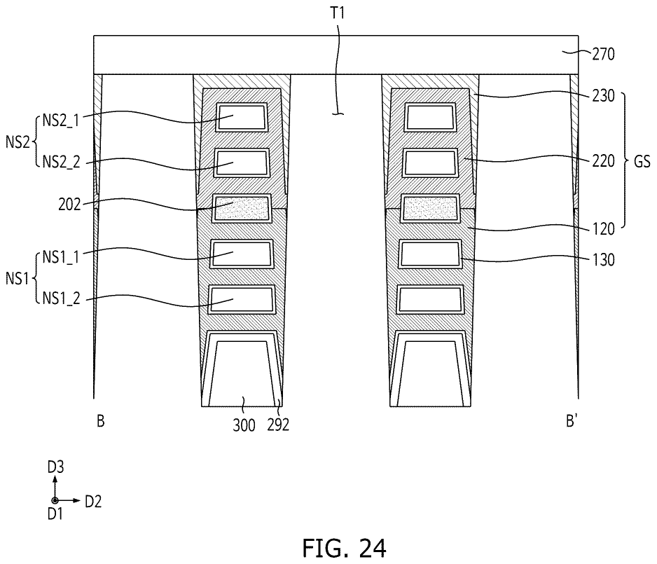

Referring to FIG. 24, a portion of the gate electrode structure GS may be removed by an etching process so as to form a first trench T1. For example, the first liner film 292 and the sacrificial insulating pattern 300 may be used as an etching mask to remove a portion of the gate electrode structure GS. The first trench T1 may separate the gate electrode structure GS. The first trench T1 may expose a side surface of the gate electrode structure GS and a lower surface of the gate capping pattern 270. A width of the first trench T1 in the second direction D2 may increase as it becomes further away from the gate capping pattern 270.

In some implementations, an upper surface of the first trench T1 may include a convex curved surface, where the upper surface of the first trench T1 may refer to a surface defined by the gate capping pattern 270. During etching of the first trench T1, a portion of the gate capping pattern 270 may be removed, resulting in a convex curved surface on the upper surface of the first trench T1.

In a method of manufacturing a semiconductor device according to some implementations of the present disclosure, the first trench T1 may be formed by using the first liner film 292 and the sacrificial insulating pattern 300 as an etching mask. Because no additional photolithography process for forming a separate mask is required to form the first trench T1, manufacturing complexity may be reduced and cost may be saved.

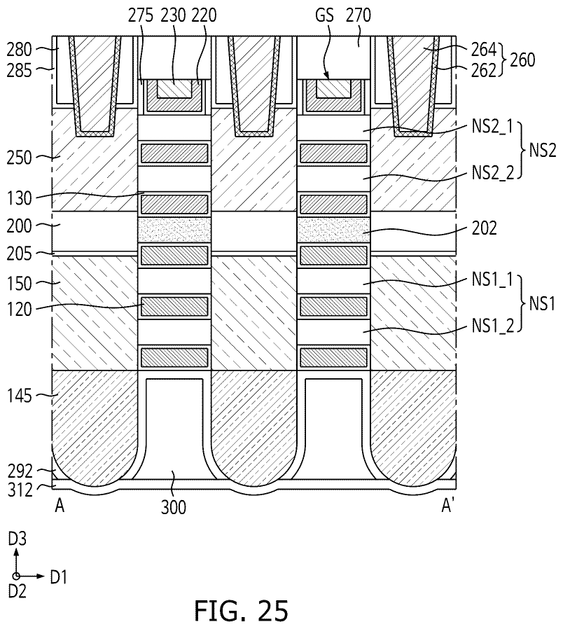

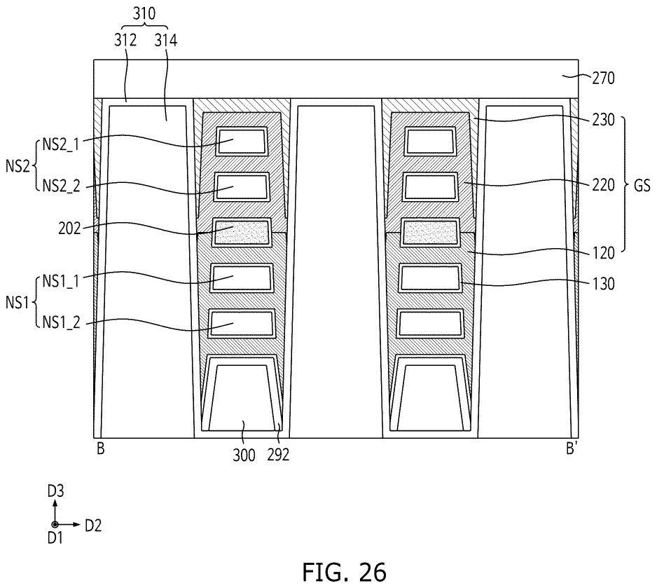

Referring to FIGS. 25 and 26, the gate separation structure 310 may be formed in the first trench T1 illustrated in FIG. 24. Specifically, the insulating liner film 312 may be formed along side and upper surfaces of the first trench T1. The insulating liner film 312 may extend on a lower surface of the sacrificial insulating pattern 300 and on a lower surface of the pre-semiconductor pattern 145. Then, the insulating filling film 314 may be formed in the insulating liner film 312. For example, the insulating filling film 314 may fill a remaining portion of the first trench T1 left after formation of the insulating liner film 312. In some implementations, an insulating material may be deposited in the insulating liner film 312, and a portion of the insulating material may be removed by a CMP process so as to form the insulating filling film 314.

Although the upper surface of the gate separation structure 310 is illustrated as planar, the present disclosure is not limited thereto. For example, when an upper surface of the gate separation trench T1 illustrated in FIG. 24 includes a convex curved surface, the upper surface of the gate separation structure 310 may be similar to that shown in FIG. 7.

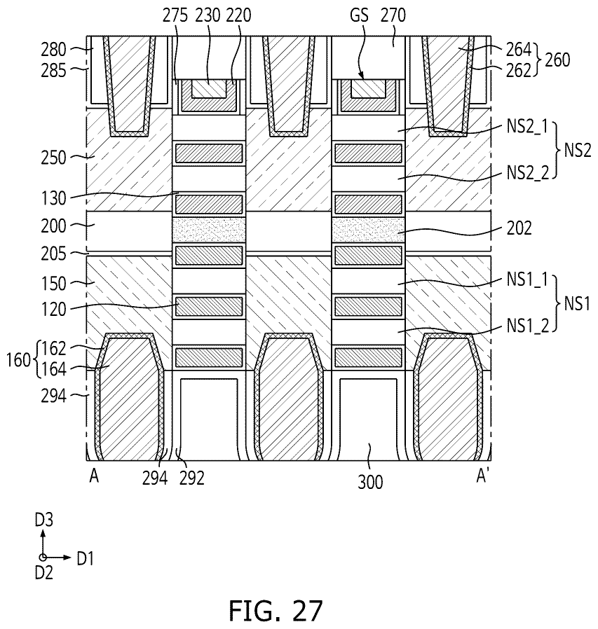

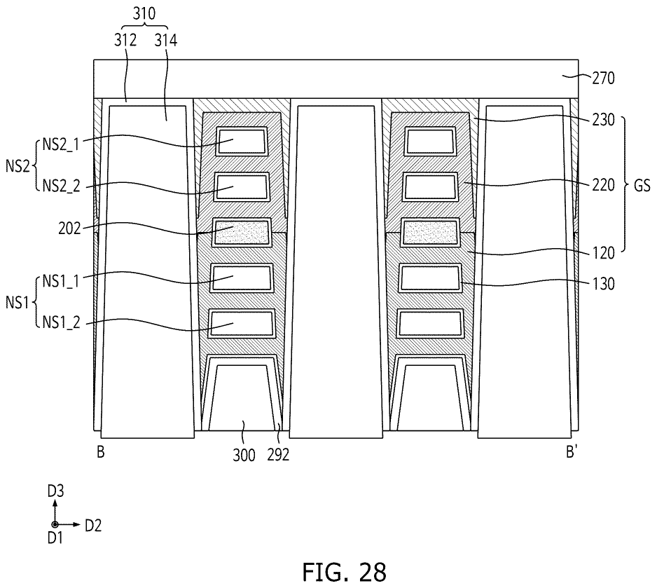

Referring to FIGS. 27 and 28, a portion of the insulating liner film 312 and the pre-semiconductor pattern 145 illustrated in FIG. 25 may be removed, and the second liner film 294 and the lower source/drain contact 160 may be formed.

Specifically, a portion of the insulating liner film 312 may be removed so as to expose the pre-semiconductor pattern 145 illustrated in FIG. 25. Then, the pre-semiconductor pattern 145 may be removed so as to expose a lower surface of the lower source/drain pattern 150. Subsequently, the second liner film 294 may be formed in a position where the pre-semiconductor pattern 145 is removed. The second liner film 294 may be formed on a side surface of the first liner film 292 and on a lower surface of the lower source/drain pattern 150.

Then, a portion of the second liner film 294 and a portion of the lower source/drain pattern 150 may be removed, and the lower source/drain contact 160 may be formed on the lower source/drain pattern 150. For example, the portion of the second liner film 294 disposed on the lower surface of the lower source/drain pattern 150 may be removed. A portion of the second liner film 294 and a portion of the lower source/drain pattern 150 may be removed by an etching process. For example, the etching process may be a dry-etch process. In addition, a portion of the second liner film 294 may be removed by the etching process so that the gate separation structure 310 and the sacrificial insulating pattern 300 are exposed.

The lower source/drain contact 160 may be formed by sequentially forming the lower source/drain contact barrier film 162 and the lower source/drain contact filling film 164 on the second liner film 294 and the lower source/drain pattern 150.

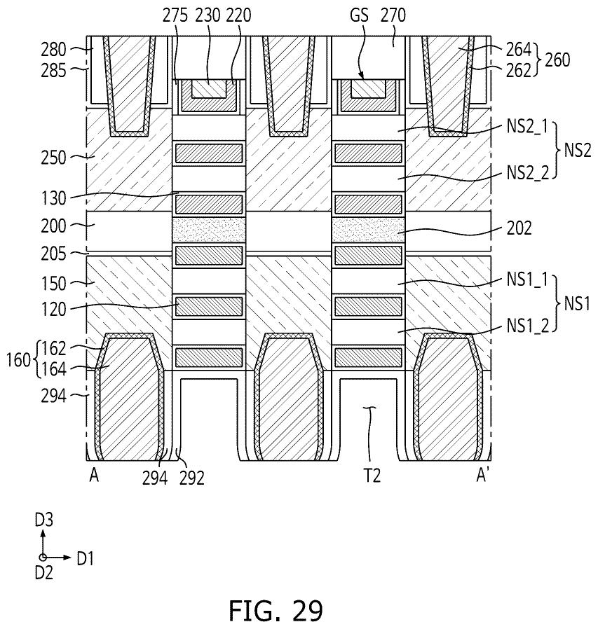

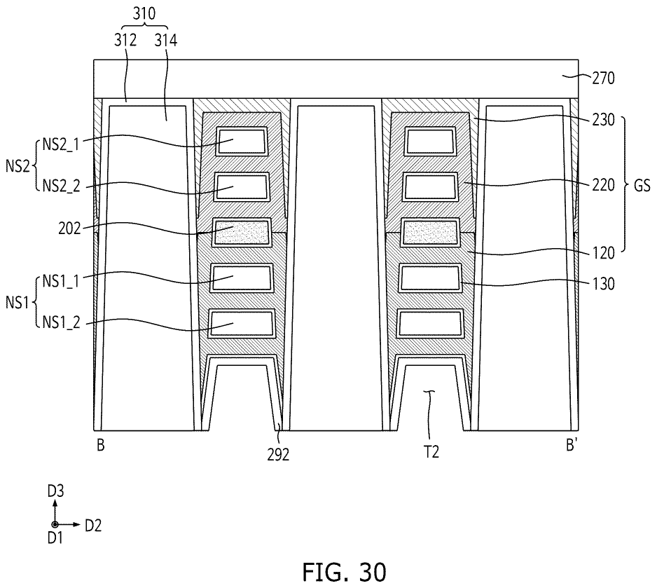

Referring to FIGS. 29 and 30, the sacrificial insulating pattern 300 may be removed so as to form a second trench T2. Side and upper surfaces of the second trench T2 may be defined by the first liner film 292.

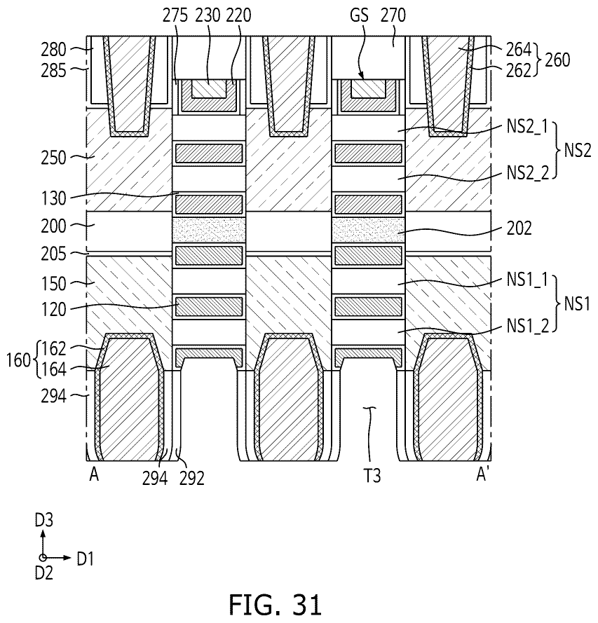

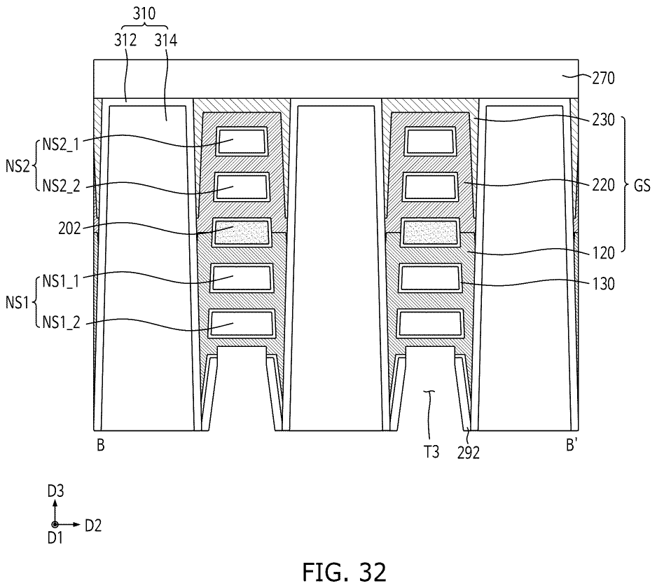

Referring to FIGS. 31 and 32, a third trench T3 may be formed by removing a portion of the first liner film 292, a portion of the gate insulating film 130, and a portion of the gate electrode structure GS. For example, the third trench T3 may be formed by performing an etching process on an upper surface of the second trench T2 illustrated in FIGS. 29 and 30.

The third trench T3 may expose lower portions of the first liner film 292 and the gate electrode structure GS. For example, the third trench T3 may expose a lower portion of the first metal pattern 120. In some implementations, a side surface of the third trench T3 may include a first portion and a second portion having different slopes, although the present disclosure is not limited thereto. A side surface of the third trench T3 may have a constant slope.

Subsequently, referring to FIGS. 2 and 3, the lower gate contact 125 may be formed on the third trench T3 illustrated in FIGS. 31 and 32. For example, the gate contact barrier film 122 and the gate contact filling film 124 may be sequentially formed on the third trench T3. When the side surface of the third trench T3 includes a first portion and a second portion having different slopes, a shape of the lower gate contact 125 may be as illustrated in FIG. 4. When the side surface of the third trench T3 has a constant slope, a shape of the lower gate contact 125 may be as illustrated in FIG. 5.

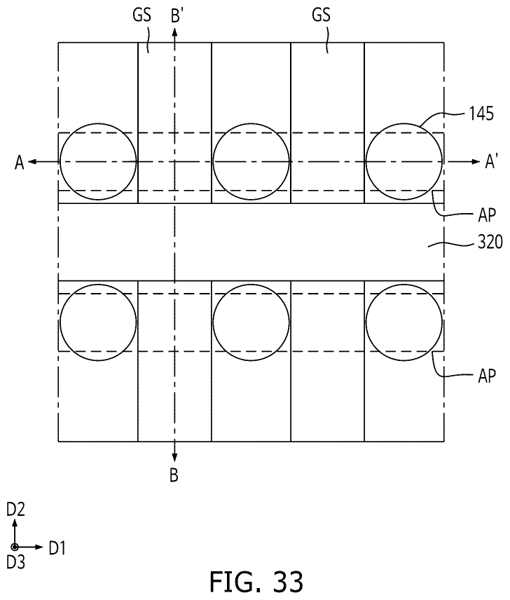

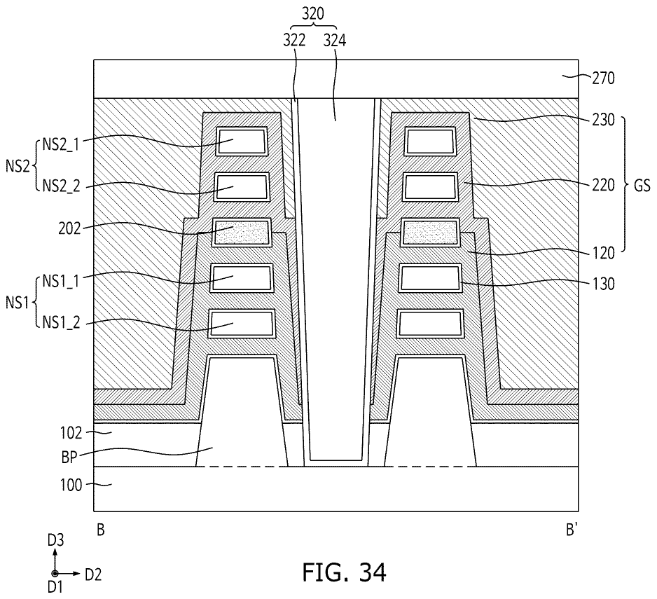

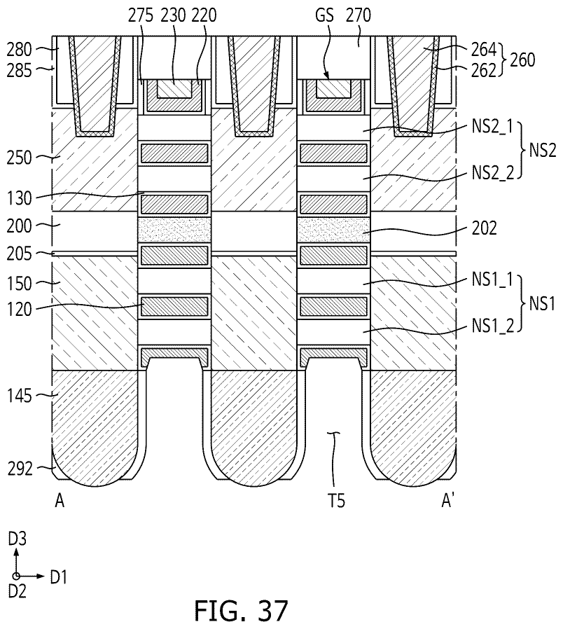

FIGS. 33-42 are views illustrating a method of manufacturing a semiconductor device according to some implementations of the present disclosure. For reference, FIG. 33 is a plan view illustrating a manufacturing method of a semiconductor device according to some implementations. FIGS. 34, 35, 36, 38, 40, and 42 are cross-sectional views illustrating cuts taken along line B-B′ of FIG. 33. FIGS. 37, 39, and 41 are cross-sectional views illustrating cuts taken along line A-A′ of FIG. 33. For convenience, elements identical to those described with reference to FIGS. 1-5 and FIGS. 11-12 are briefly described or omitted.

A cross-sectional view illustrating a cut taken along line A-A′ of FIG. 33 may be identical to FIG. 14. Referring to FIGS. 14, 33, and 34, on the substrate 100, the plurality of lower sheet patterns NS1, the plurality of upper sheet patterns NS2, the gate electrode structure GS, the gate insulating film 130, the middle insulating pattern 202, the pre-semiconductor pattern 145, the lower source/drain pattern 150, the upper source/drain pattern 250, the insulating capping layer 205, the middle interlayer insulating film 200, the upper source/drain contact 260, the gate spacer 275, the gate capping pattern 270, the upper interlayer insulating film 280, the etch-stop film 285, and the gate separation structure 320 may be formed.

A lower surface of the gate separation structure 320 may be disposed on the substrate 100. The gate separation structure 320 may separate the gate electrode structure GS. A width of the gate separation structure 320 in the second direction D2 may decrease as the gate separation structure 320 becomes further away from the gate capping pattern 270. The gate separation structure 320 may include the insulating liner film 322 and the insulating filling film 324.

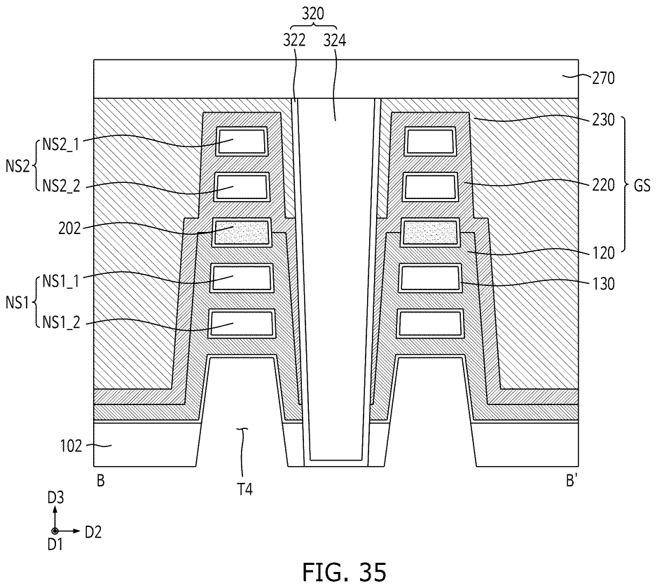

Referring to FIG. 35, the substrate 100 illustrated in FIG. 34 may be removed so as to form a fourth trench T4. The fourth trench T4 may be a space from which the lower pattern BP of the substrate 100 illustrated in FIG. 34 is removed. The fourth trench T4 may expose a side surface of the device isolation film 102 and the gate insulating film 130.

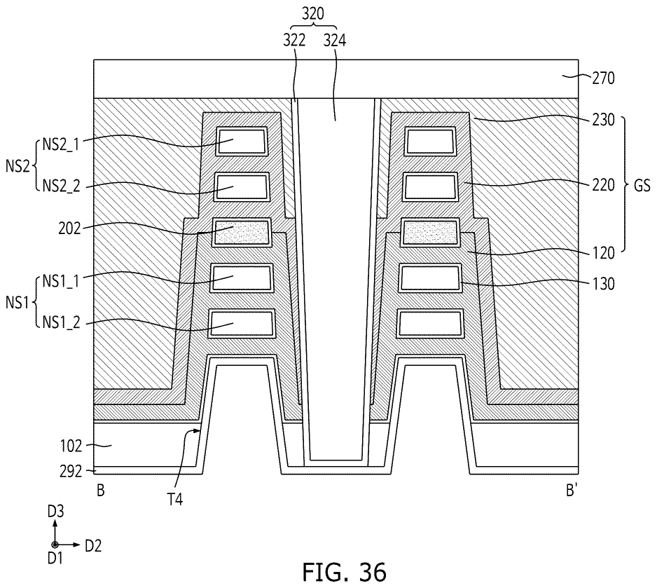

Referring to FIG. 36, the first liner film 292 may be formed on the fourth trench T4 and the device isolation film 102. For example, the first liner film 292 may extend along side and upper surfaces of the fourth trench T4. The first liner film 292 may extend along a lower surface of the device isolation film 102. In some implementations, the first liner film 292 may be formed conformally, although the present disclosure is not limited thereto.

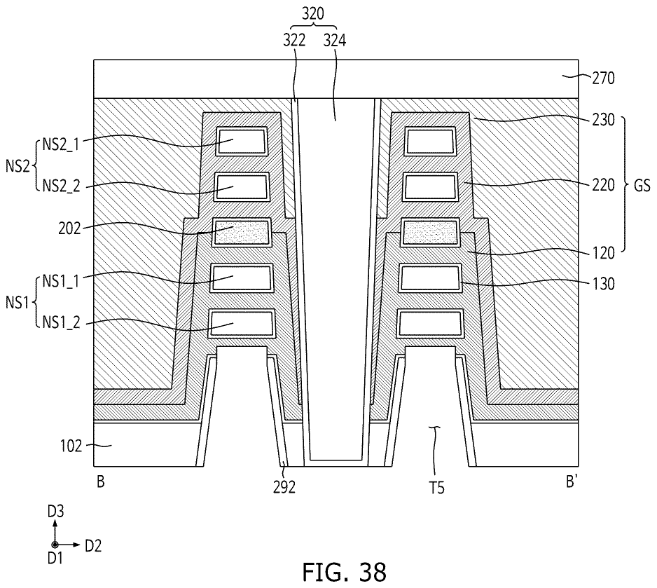

Referring to FIGS. 37 and 38, a portion of the first liner film 292 and a portion of the gate electrode structure GS may be removed by an etching process.

A portion of the first liner film 292 may be removed to expose the pre-semiconductor pattern 145 and the device isolation film 102. During the etching process, a portion of the first liner film 292 disposed on an upper surface of the fourth trench T4 illustrated in FIG. 36 and a portion of the gate electrode structure GS may be removed so as to form a fifth trench T5. The fifth trench T5 may expose the gate electrode structure GS.

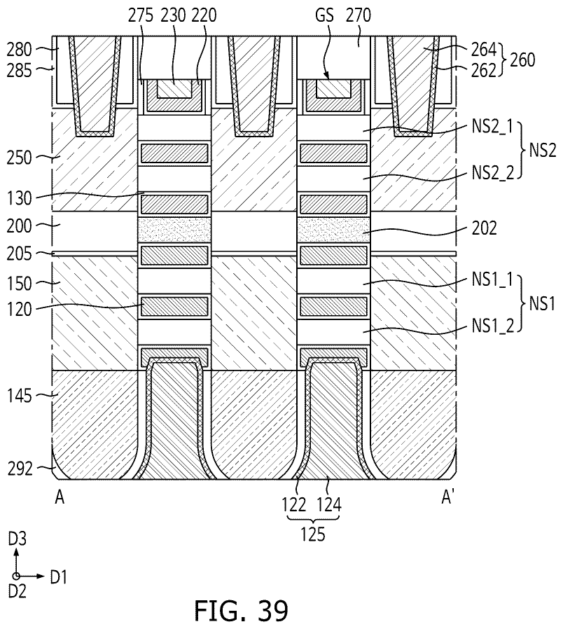

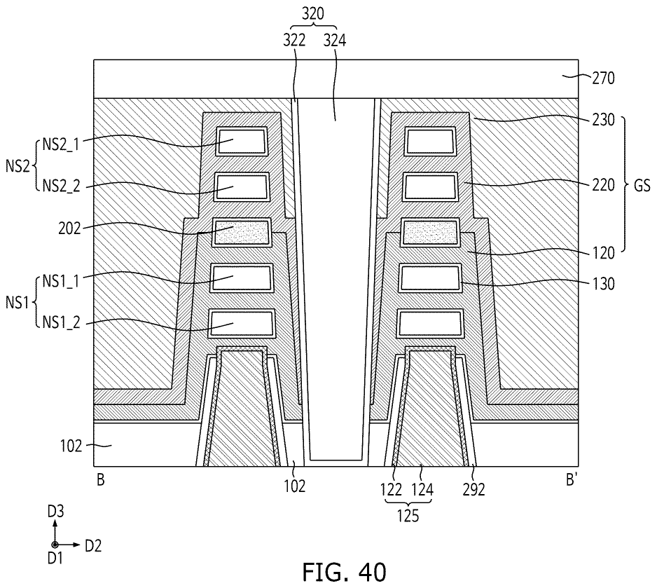

Referring to FIGS. 39 and 40, the lower gate contact 125 may be formed on the fifth trench T5 illustrated in FIG. 38. For example, the lower gate contact 125 may be formed by sequentially forming the gate contact barrier film 122 and the gate contact filling film 124 on the fifth trench T5. The first liner film 292 may surround a side surface of the lower gate contact 125.

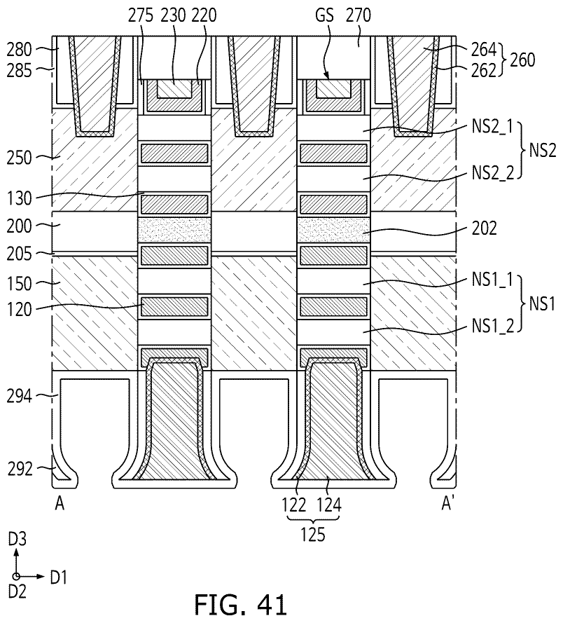

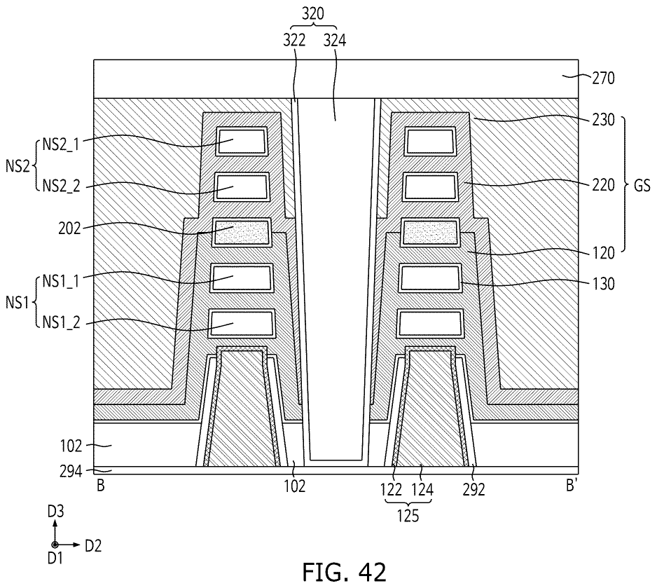

Referring to FIGS. 41 and 42, the pre-semiconductor pattern 145 may be removed, and the second liner film 294 may be formed.

For example, the pre-semiconductor pattern 145 may be removed so as to expose the lower surface of the lower source/drain pattern 150 and the first liner film 292. Then, the second liner film 294 may be formed so as to extend along a side surface of the first liner film 292, a lower surface of the lower source/drain pattern 150, a lower surface of the lower gate contact 125, and a lower surface of the device isolation film 102.

Subsequently, referring to FIGS. 11 and 12, a portion of the second liner film 294 and a portion of the lower source/drain pattern 150 may be removed, and the lower source/drain contact 160 may be formed.

While this specification contains many specific implementation details, these should not be construed as limitations on the scope of any invention or on the scope of what may be claimed, but rather as descriptions of features that may be specific to particular implementations of particular inventions. Certain features that are described in this specification in the context of separate implementations can also be implemented in combination in a single implementation. Conversely, various features that are described in the context of a single implementation can also be implemented in multiple implementations separately or in any suitable subcombination. Moreover, although features may be described above as acting in certain combinations, one or more features from a combination can in some cases be excised from the combination, and the combination may be directed to a subcombination or variation of a subcombination.

Although certain implementations of the present disclosure have been described with reference to the accompanying drawings, those of ordinary skill in the art to which the present disclosure pertains will understand that the present disclosure may be implemented in other specific forms without changing its technical idea or essential features. Therefore, it should be understood that the implementations described above are illustrative and non-limiting in all respects.

What is claimed is:

1. A semiconductor device comprising:
a plurality of lower sheet patterns spaced apart from one another in a first direction;
a plurality of upper sheet patterns spaced apart from one another in the first direction, wherein the plurality of upper sheet patterns are on the plurality of lower sheet patterns;
a gate electrode structure surrounding each lower sheet pattern of the plurality of lower sheet patterns and each upper sheet pattern of the plurality of upper sheet patterns, wherein the gate electrode structure extends in a second direction intersecting the first direction;
a lower gate contact under the gate electrode structure and overlapping the plurality of lower sheet patterns in the first direction; and
a first liner film on a side surface of the lower gate contact,
wherein a width of the gate electrode structure in the second direction decreases downward along the first direction.

2. The semiconductor device of claim 1, comprising a gate insulating film between the plurality of lower sheet patterns and the gate electrode structure, between the plurality of upper sheet patterns and the gate electrode structure, and between the first liner film and the gate electrode structure.

3. The semiconductor device of claim 1, wherein the lower gate contact comprises a first side surface and a second side surface opposite the first side surface in the second direction, and
wherein the first side surface comprises a first portion having a first slope and a second portion having a second slope different from the first slope.

4. The semiconductor device of claim 1, wherein the first liner film surrounds the side surface of the lower gate contact, and
wherein a width of the first liner film in the second direction is equal to or greater than a width of the plurality of lower sheet patterns in the second direction.

5. The semiconductor device of claim 1, comprising a gate separation structure extending in a third direction that intersects each of the first direction and the second direction, wherein the gate separation structure is on a side surface of the gate electrode structure, and
wherein a portion of the gate separation structure is on a side surface of the first liner film.

6. The semiconductor device of claim 5, comprising a gate capping pattern on an upper surface of the gate electrode structure,
wherein a width of the gate separation structure in the second direction increases further away from the gate capping pattern.

7. The semiconductor device of claim 5, comprising a lower spacer between the gate separation structure and the first liner film.

8. The semiconductor device of claim 1, wherein the first liner film comprises a material different from the plurality of lower sheet patterns.

9. The semiconductor device of claim 1, wherein the lower gate contact comprises a gate contact barrier film and a gate contact filling film, and
wherein the gate contact barrier film contacts the first liner film.

10. The semiconductor device of claim 1, wherein the plurality of lower sheet patterns comprises a first lower sheet pattern and a second lower sheet pattern sequentially stacked on the lower gate contact, and
wherein a distance from an upper surface of the first liner film to a lower surface of the first lower sheet pattern is greater than a distance from an upper surface of the first lower sheet pattern to a lower surface of the second lower sheet pattern.

11. The semiconductor device of claim 1, comprising:
a lower source/drain pattern on a first side of the plurality of lower sheet patterns in a third direction intersecting each of the first direction and the second direction;
a lower source/drain contact connected to the lower source/drain pattern; and
a second liner film surrounding a side surface of the lower source/drain contact and on a side surface of the first liner film.

12. A semiconductor device comprising:
a plurality of lower sheet patterns spaced apart from one another in a first direction;
a plurality of upper sheet patterns spaced apart from one another in the first direction, wherein the plurality of upper sheet patterns is on the plurality of lower sheet patterns;
a gate electrode structure surrounding each lower sheet pattern of the plurality of lower sheet patterns and each upper sheet pattern of the plurality of upper sheet patterns, wherein the gate electrode structure extends in a second direction intersecting the first direction;
a gate insulating film between the plurality of upper sheet patterns and the gate electrode structure and between the plurality of lower sheet patterns and the gate electrode structure;
a lower gate contact under the gate electrode structure;
a lower source/drain pattern on a first side of the plurality of lower sheet patterns in a third direction intersecting each of the first direction and the second direction;
a lower source/drain contact connected to the lower source/drain pattern and extending into a lower surface of the lower source/drain pattern; and
a first liner film and a second liner film between the lower gate contact and the lower source/drain contact,
wherein the lower gate contact and the lower source/drain contact overlap each other in the third direction.

13. The semiconductor device of claim 12, wherein the first liner film is on a side surface of the lower gate contact,
wherein the second liner film is on a side surface of the lower source/drain contact, and
wherein the first liner film contacts the second liner film.

14. The semiconductor device of claim 12, wherein the plurality of upper sheet patterns, the plurality of lower sheet patterns, and the lower gate contact are aligned in the first direction.

15. The semiconductor device of claim 12, wherein the gate insulating film is on an upper surface and a side surface of the first liner film.

16. The semiconductor device of claim 12, wherein the gate electrode structure comprises a first metal pattern surrounding the plurality of lower sheet patterns, a second metal pattern surrounding the plurality of upper sheet patterns, and a third metal pattern on the second metal pattern.

17. The semiconductor device of claim 12, comprising:
a gate separation structure extending in the third direction and on a side surface of the gate electrode structure; and
a device isolation film between the gate separation structure and the lower gate contact,
wherein the gate insulating film is on an upper surface of the device isolation film.

18. The semiconductor device of claim 12, comprising a middle insulating pattern between the plurality of lower sheet patterns and the plurality of upper sheet patterns.

19. The semiconductor device of claim 12, comprising:
an upper source/drain pattern on one side of the plurality of upper sheet patterns; and
an upper source/drain contact on the upper source/drain pattern.

20. A semiconductor device comprising:
a plurality of lower sheet patterns spaced apart from one another in a first direction;
a plurality of upper sheet patterns spaced apart from one another in the first direction and above the plurality of lower sheet patterns;
a gate electrode structure surrounding each lower sheet pattern of the plurality of lower sheet patterns and each upper sheet pattern of the plurality of upper sheet patterns, wherein the gate electrode structure extends in a second direction intersecting the first direction;
a lower gate contact under the gate electrode structure and overlapping the plurality of lower sheet patterns in the first direction;
a first liner film on a side surface of the lower gate contact;
a lower source/drain pattern on a first side of the plurality of lower sheet patterns;
an upper source/drain pattern on a first side of the plurality of upper sheet patterns;
a lower source/drain contact connected to the lower source/drain pattern;
a second liner film between the lower source/drain contact and the first liner film;
a gate separation structure extending in a third direction that intersects each of the first direction and the second direction, and wherein the gate separation structure is on a side surface of the gate electrode structure; and
a gate insulating film between each lower sheet pattern of the plurality of lower sheet patterns and the gate electrode structure, between each upper sheet pattern of the plurality of upper sheet patterns and the gate electrode structure, and between the first liner film and the gate electrode structure,
wherein the lower source/drain contact overlaps the lower gate contact in the third direction.
